(19) United States
(12) Patent Application Publication
(10) Pub. No.: US 2024/0166877 A1
(43) Pub. Date: May 23, 2024

(54) CURABLE SILICONE COMPOSITION, ENCAPSULANT, AND OPTICAL SEMICONDUCTOR DEVICE

(71) Applicant: DuPont Toray Specialty Materials Kabushiki Kaisha, Tokyo (JP)

(72) Inventors: Shunya TAKEUCHI, Chiba (JP); Akito HAYASHI, Chiba (JP); Akihiko KOBAYASHI, Chiba (JP); Takayuki ASO, Chiba (JP); Yuri IGUCHI, Chiba (JP)

(21) Appl. No.: 18/548,789

(22) PCT Filed: Mar. 8, 2022
(86) PCT No.: PCT/JP2022/010002

§ 371 Date: Sep. 1, 2023

(30) Foreign Application Priority Data
Mar. 8, 2021 (JP) 2021-036230

(51) Int. Cl. C08L 83/04; H01L 23/29; H01L 33/56

(52) U.S. Cl. CPC C08L 83/04; H01L 23/293; H01L 33/56; C08G 77/70

(57) ABSTRACT

Provided is a curable silicone composition which exhibits a practically effective pot life, is curable at a low temperature, and which can be used to form a cured product that has superior surface smoothness, is transparent, and has high hardness. This curable silicone composition contains: (A) a resinous alkenyl group-containing organopolysiloxane having, per molecule, at least two alkenyl groups and at least one aryl group; (B) a resinous organohydrogenpolysiloxane having, in one molecule, at least two hydrogen atoms bonded to silicon atoms; (C) a molecular chain side chain polyether-modified organopolysiloxane, a phenyl-modified organopolysiloxane, a non-terminal hydroxyl group-containing dimethyl polysiloxane that does not contain an aryl group, and a phenolic antioxidant, as well as an adhesive that has a wettability improvement effect and is selected from a combination of these; and (D) a curing reaction inhibitor.

### TECHNICAL FIELD

The present invention relates to a curable silicone composition, and more specifically it relates to a curable silicone composition which can be favorably used in an optical semiconductor encapsulant. The present invention also relates to an encapsulant comprising such a curable silicone composition and to an optical semiconductor device encapsulated with the encapsulant.

### BACKGROUND OF THE INVENTION

Curable silicone compositions are employed in a wide range of industrial fields because, after hardening, they form a cured product with outstanding heat resistance, cold resistance, electrical insulating properties, weather resistance, water repellence and transparency. In particular, the cured product is widely used as a silicone sealing material for optical members, and is especially used in optical semiconductor devices such as light-emitting diodes (LEDs), because the cured product is less likely to change color than other organic materials and there is little reduction in physical properties such as durability.

In particular, curable organopolysiloxane compositions that harden via a hydrosilylation reaction are used as protective coatings, encapsulants, and the like for optical semiconductor elements in optical semiconductor devices such as photocouplers, light-emitting diodes, and solid-state imaging elements. Because optical semiconductor elements emit and receive light, it is required that protective coatings and encapsulants on these optical semiconductor elements do not absorb or scatter light.

For this reason, hydrosilylation reaction-curable organopolysiloxane compositions that form a cured product having a high refractive index and light transmittance by use of organopolysiloxane having a high phenyl group content have been proposed for optical semiconductor applications.

For example, Patent Document 1 discloses a hydrosilylation reaction-curable organopolysiloxane composition comprising: (A) methyl-phenyl-alkenyl polysiloxane which has at least two silicon atom-bonded alkenyl groups per molecule, in which diphenylsiloxane units are ≤5 mol % of total siloxane units, and at least 20 mol % of all silicon atom-bonded organic groups in the molecule are phenyl groups; (B) methyl-phenyl-hydrogen polysiloxane which has at least two silicon atom-bonded hydrogen atoms per molecule, in which diphenylsiloxane units are ≤5 mol % of total siloxane units and at least 20 mol % of all silicon atom-bonded organic groups in the molecule are phenyl groups; and (C) a hydrosilylation reaction catalyst, characterized in that diphenylsiloxane units in this composition are ≤5 mol % of total siloxane units.

Patent Document 2 discloses a curable organopolysiloxane composition comprising at least: (A) an organopolysiloxane of average structural formula: R¹ₐSiO_{(4-a)/2} (in the formula, R¹ designates an unsubstituted or halogen-substituted monovalent hydrocarbon group; however, in one molecule at least two R are alkenyl groups and at least 30 mol % of all R¹ are aryl groups; and “a” is a number ranging from 0.6 to 2.1); (B) an organopolysiloxane that contains in one molecule at least two silicon atom-bonded hydrogen atoms, in which at least 15 mol % of all silicon atom-bonded organic groups are aryl groups; (C) a branched-chain organopolysiloxane of average unit formula: (R²SiO_{3/2})_{b}(R²₂SiO_{2/2})_{c}(R²₃SiO_{1/2})_{d}(SiO_{4/2})ₑ(XO_{1/2})_{f} {in the formula, each R² independently designates an alkyl group, alkenyl group, aryl group, or an epoxy-containing organic group; however, in one molecule at least 5 mol % of all R² are alkenyl groups, at least 15 mol % are aryl groups, and at least 10 mol % are epoxy-containing organic groups; X designates a hydrogen atom or an alkyl group; and b is a positive number, c is 0 or a positive number, d is 0 or a positive number, e is 0 or a positive number, f is 0 or a positive number, c/b is a number ranging from 0 to 10, d/b is a number ranging from 0 to 5, e/(b+c+d+e) is a number ranging from 0 to 0.3, and f/(b+c+d+e) is a number ranging from 0 to 0.02}; and (D) a hydrosilylation catalyst, wherein the content of component (B) is such an amount that a molar ratio of the silicon atom-bonded hydrogen atoms contained in component (B) to the alkenyl groups contained in components (A) and (C) is in the range of 0.1 to 5, the content of component (C) is 0.1 to 20 parts by mass per 100 parts by mass of the total of components (A) and (B), and the content of component (D) is an amount sufficient to accelerate curing of the composition.

Patent Document 3 discloses a curable organopolysiloxane composition characterized by comprising at least: (A) a diorganopolysiloxane that has at least two alkenyl groups in one molecule, wherein at least 70 mol % of all siloxane units are methylphenylsiloxane units (however, the total content of 1,3,5-trimethyl-1,3,5-triphenylcyclotrisiloxane and 1,3,5,7-tetramethyl-1,3,5,7-tetraphenylcyclotetrasiloxane is no more than 5 weight %); (B) an organopolysiloxane that has at least two silicon atom-bonded hydrogen atoms in one molecule, wherein at least 15 mol % of the silicon atom-bonded organic groups are phenyl groups {in a quantity such that the number of moles of silicon atom-bonded hydrogen atoms in component (B) is 10 to 500% relative to the total number of moles of alkenyl groups in component (A)}; and (C) a hydrosilylation reaction catalyst (in a quantity sufficient to cure the composition).

Patent Document 4 discloses a curable organopolysiloxane composition characterized by comprising: (A) an organopolysiloxane having at least two alkenyl groups in a molecule; (B) an organopolysiloxane having at least two silicon atom-bonded hydrogen atoms in a molecule; (C) a polyether-modified silicone having a number average molecular weight of 1000 to 100,000 and comprising repeating units represented by a general formula; and (D) a hydrosilylation reaction catalyst.

However, conventional curable silicone compositions ordinarily require high-temperature treatment for a long period of time in order to cure, so when they are used as an encapsulant for a semiconductor element, the shape may contract during curing, and as a result, flexible substrates may warp, the patterning precision in the semiconductor element mounting process may degrade, or mounted electronic elements and the like may sustain damage from heat. In addition, although curability of the curable silicone composition improves when the amount of curing catalyst is increased to improve curability, there is the problem that the cured product may take on coloration. Moreover, there is also the problem that conventional curable silicone compositions that have a high refractive index and which contain aryl groups may have insufficient wettability towards organic substrates such as polycarbonates, and the cured product may have insufficient surface smoothness.

Additionally, hydrosilylation reaction-curable organopolysiloxane compositions having high heat resistance at particularly high temperatures have also been developed in the past.

For example, Patent Document 5 discloses a curable organopolysiloxane composition comprising: (A) a branched organopolysiloxane having at least one silicon-bonded alkenyl group and at least one silicon-bonded aryl group per molecule, and having siloxane units represented by the general formula: RSiO_{3/2} (where R is a substituted or unsubstituted monovalent hydrocarbon group); (B) a linear organopolysiloxane with both terminal ends of the molecular chain blocked by silicon-bonded hydrogen atoms and having at least one silicon-bonded aryl group per molecule; (C) a hydrosilylation reaction catalyst; and (D) a low molecular weight siloxane having at least one silicon-bonded alkenyl group per molecule, represented by the average formula: (R⁵³SiO_{1/2})_{f}(R⁵²SiO_{2/2})_{g} (R⁵SiO_{3/2})ₕ(SiO_{4/2})ᵢ (where each R⁵ can be the same or different and is independently selected from a substituted or unsubstituted monovalent hydrocarbon group, wherein at least one R⁵ per molecule is an alkenyl group, with the proviso that the ratio between alkenyl groups and silicon atoms is from 0.3 to 1, and f, g, h, and i are independently 0 or a positive number), wherein the weight average molecular weight Mw of the siloxane is less than 1000 g/mol.

Patent Document 6 discloses an addition curing type silicone composition comprising the following components (A) to (C): (A) organopolysiloxane represented by a specific composition formula, having at least two alkenyl groups in one molecule and having a network structure; (B) branched organo-hydrogen polysiloxane represented by a specific formula and having at least two hydrosilyl groups in one molecule; and (C) a hydrosilylation catalyst in a catalytic quantity.

Patent Document 7 discloses a curable resin composition comprising: (A) a straight-chain organopolysiloxane having at least two silicon atom-bonded hydrogen atoms and at least one aryl group in one molecule and having an average degree of polymerization of greater than 10; (B) a branched-chain organopolysiloxane having at least three alkenyl groups and at least one aryl group in one molecule; and (C) a hydrosilylation reaction catalyst, wherein the proportion of diphenylsiloxane units relative to all siloxane units including the straight-chain organopolysiloxane (A) and the branched-chain organopolysiloxane (B) is 10 mol % or greater.

However, with conventional highly heat-resistant curable silicone compositions, there is the problem that the pot life and curability of the curable silicone compositions are insufficient.

### PRIOR ART DOCUMENTS

### Patent Documents

Patent Document 1: JP 2012-507582 A
Patent Document 2: JP 2010-1335 A
Patent Document 3: JP 2010-84118 A
Patent Document 4: WO 2019/026754 A1
Patent Document 5: JP 2019-524959 A
Patent Document 6: JP 2016-204423 A
Patent Document 7: WO 2015/136820 A1

### SUMMARY OF THE INVENTION

### Problems to be Solved by the Invention

The objective of the present invention is to provide a curable silicone composition that exhibits an effective pot life in practical terms and excellent curability at low temperatures and can form a cured product that has excellent surface smoothness, is transparent, and has high hardness.

Another objective of the present invention is to provide a curable silicone composition that exhibits an effective pot life in practical terms and excellent curability at low temperatures and can form a cured product that is transparent and has high hardness even when exposed to high temperatures for a long period of time.

Another objective of the present invention is to provide an encapsulant comprising a curable silicone composition of the present invention. A further objective of the present invention is to provide an optical semiconductor device encapsulated with the encapsulant of the present invention.

### Means for Solving the Problems

As a result of concerted studies in order to solve the problems above, the present inventors arrived at the present invention with the discovery that, surprisingly, a cured product which can be efficiently cured even at low temperature and in a short period of time, and has superior transparency, high hardness, and a smooth surface can be formed by means of a curable silicone composition comprising: (A) a resinous alkenyl group-containing organopolysiloxane which has at least two alkenyl groups and at least one aryl group per molecule; (B) a resinous organo-hydrogen polysiloxane which has at least two silicon atom-bonded hydrogen atoms per molecule; (C) an additive having a wettability improving effect selected from a molecular-chain side chain polyether-modified organopolysiloxane, a phenol-modified organopolysiloxane, a terminal hydroxy group-containing dimethylpolysiloxane that does not include an aryl group, and a phenolic antioxidant, and also combinations thereof, (D) a curing reaction inhibitor.

Therefore, the present invention relates to a curable silicone composition comprising:
(A) a resinous alkenyl group-containing organopolysiloxane which has at least two alkenyl groups and at least one aryl group per molecule;
(B) a resinous organo-hydrogen polysiloxane which has at least two silicon atom-bonded hydrogen atoms per molecule;
(C) an additive having a wettability improving effect selected from a molecular-chain side chain polyether-modified organopolysiloxane, a phenol-modified organopolysiloxane, a terminal hydroxy group-containing dimethylpolysiloxane that does not include an aryl group, and a phenolic antioxidant, and also combinations thereof; and
(D) a curing catalyst.

The curable silicone composition preferably further comprises a straight-chain organo-hydrogen polysiloxane.

The polyether group of the molecular-chain side chain polyether-modified organopolysiloxane of component (C) preferably includes a polyoxyethylene unit.

The phenol-modified organopolysiloxane of component (C) preferably is a straight chain and includes a phenol group-containing organic group at both ends of the molecular chain.

The terminal hydroxy group-containing dimethylpolysiloxane that does not include an aryl group of component (C) preferably is a straight chain and includes a hydroxy group at both ends of the molecular chain.

The phenolic antioxidant of component (C) is preferably 2,6-di-tert-butyl-p-cresol.

The content of molecular-chain side chain polyether-modified organopolysiloxane (C) is preferably ≥0.01 mass % and ≤10 mass % of the total mass of alkenyl group-containing organopolysiloxane and organo-hydrogen polysiloxane.

The content of resinous organo-hydrogen polysiloxane (B) is preferably ≥1 mass % of the total mass of alkenyl group-containing organopolysiloxane and organo-hydrogen polysiloxane.

The curing catalyst (D) preferably is a platinum-based catalyst and includes ≥0.01 ppm and ≤15 ppm of platinum atoms relative to the total mass of curable silicone composition.

A molar ratio (H/Vi) of hydrogen atoms to alkenyl groups originating from the organopolysiloxane component is preferably 0.9 to 1.3.

The curable silicone composition preferably further includes, other than component (A), alkenyl group-containing organopolysiloxane comprising solely epoxy group-containing resinous organopolysiloxane, alkenyl group-containing cyclic organopolysiloxane and/or M units and Q units.

The present invention also relates to a curable silicone composition comprising:
(A) a resinous alkenyl group-containing organopolysiloxane which has at least two alkenyl groups and at least one aryl group per molecule;
(F) an alkenyl group-containing organopolysiloxane comprising solely M units and Q units;
(B) a resinous organo-hydrogen polysiloxane which has at least two silicon atom-bonded hydrogen atoms per molecule;
(E) ethynylcyclohexanol; and
(D) a curing catalyst,
wherein a molar ratio (H/Vi) of hydrogen atoms to alkenyl groups originating from the organopolysiloxane component is 0.98 to 1.2, and
the content of resinous organopolysiloxane that contains alkenyl groups that are bonded to silicon atoms of siloxane units (D units), which are represented by SiO_{2/2}, is <50 mass % of the total mass of alkenyl group-containing organopolysiloxane and organo-hydrogen polysiloxane.

The content of (F) alkenyl group-containing organopolysiloxane comprising solely M units and Q units is preferably ≥2 mass % and ≤20 mass % of the total mass of alkenyl group-containing polysiloxane and organo-hydrogen polysiloxane.

The content of (B) resinous organo-hydrogen polysiloxane is preferably ≥1 mass % and ≤15 mass % of the total mass of alkenyl group-containing organopolysiloxane and organo-hydrogen polysiloxane.

The curing catalyst (D) preferably is a platinum-based catalyst and contains ≥0.01 ppm and ≤8 ppm of platinum atoms relative to the total mass of curable silicone composition.

The content of straight-chain organo-hydrogen polysiloxane is preferably ≥25 mass % of the total mass of resinous alkenyl group-containing organopolysiloxane of component (A).

The present invention also relates to an encapsulant comprising the curable silicone composition of the present invention.

The present invention also relates to an optical semiconductor device comprising a cured product of the encapsulant according to the present invention.

### Effect of the Invention

By virtue of a curable silicone composition according to an embodiment of the present invention, it is possible to provide a curable silicone composition that exhibits an effective pot life in practical terms and excellent curability at low temperature and that can form a cured product that is transparent, has high hardness, and has a smooth surface shape.

In addition, by virtue of a curable silicone composition according to another embodiment of the present invention, it is possible to provide a curable silicone composition that can exhibit an effective pot life in practical terms and excellent curability at low temperature and that can form a cured product that exhibits superior transparency even after heating for a long period of time.

### MODE FOR CARRYING OUT THE INVENTION

[Curable Silicone Composition]

A curable silicone composition of embodiment 1 of the present invention comprises at least:
(A) a resinous alkenyl group-containing organopolysiloxane which has at least two alkenyl groups and at least one aryl group per molecule;
(B) a resinous organo-hydrogen polysiloxane which has at least two silicon atom-bonded hydrogen atoms per molecule;
(C) an additive having a wettability improving effect selected from a molecular-chain side chain polyether-modified organopolysiloxane, a phenol-modified organopolysiloxane, a terminal hydroxy group-containing dimethylpolysiloxane that does not include an aryl group, and a phenolic antioxidant, and also combinations thereof; and
(D) a curing catalyst.

By virtue of such an embodiment 1 of the present invention, it is possible to provide a curable silicone composition that exhibits an effective pot life in practical terms and superior curability at low temperatures, and enables a cured product having a smooth surface shape to be formed on a substrate. In addition, the curable silicone composition of embodiment 1 of the present invention can form a cured product that also exhibits high hardness and superior transparency after heating.

In addition, a curable silicone composition of embodiment 2 of the present invention comprises:
(A) a resinous alkenyl group-containing organopolysiloxane which has at least two alkenyl groups and at least one aryl group per molecule;
(F) an alkenyl group-containing organopolysiloxane comprising solely M units and Q units;
(B) a resinous organo-hydrogen polysiloxane which has at least two silicon atom-bonded hydrogen atoms per molecule;
(E) ethynylcyclohexanol; and
(D) a curing catalyst,
wherein a molar ratio (H/Vi) of hydrogen atoms to alkenyl groups originating from the organopolysiloxane component is 0.98 to 1.2, and
the content of resinous organopolysiloxane that contains alkenyl groups that are bonded to silicon atoms of siloxane units (D units), which are represented by SiO₂/2, is <50 mass % of the total mass of alkenyl group-containing organopolysiloxane and organo-hydrogen polysiloxane.

By virtue of such an embodiment 2 of the present invention, it is possible to provide a curable silicone composition that exhibits an effective pot life in practical terms and superior curability at low temperatures and can form a cured product that exhibits superior transparency even after heating for a long period of time.

Each of the components of a curable silicone composition of the present invention is described in detail below.

(A) Resinous Alkenyl Group-Containing Organopolysiloxane which has at Least Two Alkenyl Groups and at Least One Aryl Group Per Molecule

Component (A) is the main component of the composition, and is a resinous organopolysiloxane which has at least two alkenyl groups and at least one aryl group per molecule. A curable silicone composition of the present invention can include one type of alkenyl group-containing organopolysiloxane (A), or can include two or more types of alkenyl group-containing organopolysiloxanes (A).

The molecular structure of component (A) is resinous. In this specification, resinous means having a branched or three-dimensional network structure in the molecular structure, and means, for example, the inclusion of at least one siloxane unit represented by SiO_{3/2} (T unit) or siloxane unit represented by SiO_{4/2} (Q unit).

Examples of alkenyl groups which can be included in component (A) include C2-12 alkenyl groups such as vinyl groups, allyl groups, butenyl groups, pentenyl groups, hexenyl groups, heptenyl groups, octenyl groups, nonenyl groups, decenyl groups, undecenyl groups and dodecenyl groups, and vinyl groups are preferred.

Examples of aryl groups included in component (A) include C6-20 aryl groups such as phenyl groups, tolyl groups, xylyl groups and naphthyl groups, and phenyl groups are preferred.

Silicon atom-bonded organic groups other than alkenyl groups and aryl groups included in component (A) include halogen-substituted or unsubstituted monovalent hydrocarbon groups other than alkenyl groups and aryl groups; examples include C1-12 alkyl groups such as methyl groups, ethyl groups, propyl groups, isopropyl groups, butyl groups, isobutyl groups, tert-butyl groups, pentyl groups, neopentyl groups, hexyl groups, cyclohexyl groups, heptyl groups, octyl groups, nonyl groups, decyl groups, undecyl groups and dodecyl groups; C7-20 aralkyl groups such as benzyl groups, phenethyl groups and phenylpropyl groups; and the above groups in which some or all of the hydrogen atoms are substituted with a halogen atom such as a fluorine atom, chlorine atom or bromine atom. It should be noted that the silicon atoms in component (A) can also have a small quantity of hydroxyl groups or alkoxy groups such as methoxy groups or ethoxy groups within a range that will not detract from the objective of the present invention. The silicon atom-bonded groups other than alkenyl groups and aryl groups of component (A) are preferably selected from C1-6 alkyl groups, especially methyl groups, and C6-20 aryl groups, especially phenyl groups.

In this specification, the resinous alkenyl group-containing organopolysiloxane which has at least two alkenyl groups and at least one aryl group per molecule of component (A) can mean a resinous alkenyl group-containing organopolysiloxane that does not include an epoxy group-containing organic group as an organic group in which an epoxy group is bonded to a silicon atom.

In an embodiment of the present invention, component (A) may preferably be represented by average unit formula (I):

(R¹₃SiO_{1/2})ₐ(R¹₂SiO_{2/2})_{b}(R¹SiO_{3/2})_{c}(SiO_{4/2})ₐ(XO_{1/2})ₑ Average Unit Formula (I):

(In formula (I), R¹ are the same or different halogen-substituted or unsubstituted monovalent hydrocarbon groups, however, in one molecule at least two R are alkenyl groups, and at least one R¹ is an aryl group; 0≤a<1, 0≤b<1, 0≤c<0.9, 0≤d<0.5, and 0≤e<0.4, a+b+c+d=1.0, and c+d>0).

Examples of halogen-substituted or unsubstituted monovalent hydrocarbon groups as R¹ in formula (I) above include C1-12 alkyl groups such as methyl groups, ethyl groups, propyl groups, isopropyl groups, butyl groups, isobutyl groups, tert-butyl groups, pentyl groups, neopentyl groups, hexyl groups, cyclohexyl groups, heptyl groups, octyl groups, nonyl groups, decyl groups, undecyl groups and dodecyl groups; C6-20 aryl groups such as phenyl groups, tolyl groups, xylyl groups and naphthyl groups; C7-20 aralkyl groups such as benzyl groups, phenethyl groups and phenylpropyl groups; C2-12 alkenyl groups such as vinyl groups, allyl groups, butenyl groups, pentenyl groups, hexenyl groups, heptenyl groups, octenyl groups, nonenyl groups, decenyl groups, undecenyl groups and dodecenyl groups; and the above groups in which some or all of the hydrogen atoms are substituted with a halogen atom such as a fluorine atom, chlorine atom or bromine atom. R can be a small quantity of hydroxyl groups or alkoxy groups such as methoxy groups or ethoxy groups within a range that will not detract from the objective of the present invention. R¹ is preferably selected from C1-6 alkyl groups, especially a methyl group, C2-6 alkenyl groups, especially a vinyl group, or C6-20 aryl groups, especially a phenyl group.

X in formula (I) above is a hydrogen group or an alkyl group. An X alkyl group is preferably a C1-3 alkyl group, and specific examples are a methyl group, ethyl group and propyl group.

In formula (I) above, a is preferably in the range 0.1≤a≤0.8, more preferably in the range 0.15≤a≤0.6, and even more preferably in the range 0.2≤a≤0.4. In formula (I) above, b is preferably in the range 0≤b≤0.6, more preferably in the range 0≤b≤0.5, and especially in the range 0≤b≤0.4. In formula (I) above, c is preferably in the range 0.2≤c≤0.9, more preferably in the range 0.4≤c≤0.85, and especially in the range 0.6≤c≤0.8. In formula (I) above, d is preferably in the range 0≤d≤0.4, more preferably in the range 0≤d≤0.25, and especially in the range 0≤d≤0.1. In formula (I) above, e is preferably in the range 0≤e≤0.15, more preferably in the range 0≤e≤0.1, and especially in the range 0≤e≤0.05.

In a preferred embodiment of the present invention, c in above formula (I) is greater than 0, i.e., the resinous alkenyl group-containing organopolysiloxane of component (A) includes a siloxane unit represented by SiO_{3/2} (T unit). The resinous organopolysiloxane of component (A) can include or not include, but preferably does not include, a siloxane unit represented by SiO_{4/2} (Q unit).

In a preferred embodiment of the present invention, in above formula (I), the resinous alkenyl group-containing organopolysiloxane of component (A) can include or not include, but preferably does not include, a siloxane unit represented by SiO_{2/2} (D unit).

In a preferred embodiment of the present invention, the resinous alkenyl group-containing organopolysiloxane of component (A) contains an alkenyl group at end of the molecule. The resinous alkenyl group-containing organopolysiloxane of component (A) preferably has an alkenyl group in a siloxane unit represented by SiO_{1/2} (M unit), and can include or not include, but preferably does not include, an alkenyl group in molecular-chain side chains (i.e., a siloxane unit represented by SiO_{2/2} (D unit) or a siloxane unit represented by SiO_{3/2} (T unit)).

There are no particular restrictions as to the content of alkenyl groups in the entirety of the silicon atom-bonded organic groups in the resinous alkenyl group-containing organopolysiloxane of component (A); for example, the content can be ≥5 mol % of the total silicon atom-bonded organic groups, preferably ≥10 mol %, and more preferably ≥15 mol %, and the content can also be ≤40 mol % of the total silicon atom-bonded organic groups, preferably ≤30 mol %, and more preferably ≤20 mol %. It should be noted that in the present specification, the content of alkenyl groups included in the organopolysiloxane component can be determined, for example, by analytical methods such as Fourier-transform infrared spectroscopy (FT-IR), nuclear magnetic resonance (NMR), or by the titration method below.

A method for determining the quantity of alkenyl groups in each component by means of a titration method will be described. The content of alkenyl groups in organopolysiloxane components can be determined with good precision by a titration method commonly known as the Wijs method. The principle is as follows. First, the alkenyl groups in the organopolysiloxane starting material are subjected to an addition reaction with iodine monochloride as shown in formula (1). Then, excess iodine monochloride is reacted with potassium iodide to liberate free iodine by the reaction shown in formula (2). The free iodine is then titrated with a sodium thiosulfate solution.

CH₂═CH—+2ICl →CH₂I—CHCl—+ICl (excess) Formula (1)

ICl+KI →I₂+KCl Formula (2)

The quantity of alkenyl groups in the component can be determined from the difference between the quantity of sodium thiosulfate required in the titration and the quantity for titrating a separately prepared blank solution.

The aryl group content of the resinous organopolysiloxane of component (A) (mol % of aryl groups in the entirety of the silicon atom-bonded functional groups of resinous organopolysiloxane) can be designed as desired, but the content is ordinarily ≥5 mol %, preferably ≥10 mol %, more preferably ≥15 mol %, even more preferably ≥20 mol %, preferentially ≥30 mol %, and particularly preferably ≥35 mol %, and the content can also be ≤80 mol %, preferably ≤70 mol %, even more preferably ≤65 mol %, preferentially ≤60 mol %, and particularly preferably ≤55 mol %. It should be noted that in the present specification, the content of aryl groups included in the organopolysiloxane component can be determined, for example, by analyses such as Fourier-transform infrared spectroscopy (FT-IR) or nuclear magnetic resonance (NMR).

The organopolysiloxane of component (A) is preferably a solid or semisolid at 25° C. Although the number-average molecular weight of the organopolysiloxane of component (A) is not particularly restricted, it is preferably within the range of 500 to 10,000.

Component (A) is the main agent of the curable silicone composition of the present invention, and the content thereof, based on the total mass of alkenyl group-containing organopolysiloxane and organo-hydrogen polysiloxane included in the curable silicone composition of the present invention, is preferably ≥40 mass %, more preferably ≥50 mass %, even more preferably ≥55 mass %, and particularly preferably ≥60 mass %. In addition, based on the total mass of alkenyl group-containing organopolysiloxane and organo-hydrogen polysiloxane included in the curable silicone composition of the present invention, the content of component (A) is preferably ≤90 mass %, more preferably ≤80 mass %, even more preferably ≤70 mass %, and particularly preferably ≤65 mass %.

(Other Alkenyl Group-Containing Organopolysiloxanes)

Other than main agent component (A) of the curable silicone composition of the present invention, the curable silicone composition of the present invention can include alkenyl group-containing organopolysiloxanes that include at least two alkenyl groups per molecule. Such other alkenyl group-containing organopolysiloxanes are not particularly restricted, and examples include epoxy group-containing resinous organopolysiloxane, alkenyl group-containing cyclic organopolysiloxane, and alkenyl group-containing organopolysiloxane comprising solely M units and Q units.

(Epoxy Group-Containing Resinous Organopolysiloxane)

In one embodiment of the present invention, the curable silicone composition of the present invention can include epoxy group-containing resinous organopolysiloxane. The curable silicone composition of the present invention can include one type of epoxy group-containing resinous organopolysiloxane, or can include a combination of two or more types of epoxy group-containing resinous organopolysiloxanes.

An epoxy group-containing resinous organopolysiloxane may preferably be represented by average unit formula (II):

(R⁹₃SiO_{1/2})ₐ(R¹⁰₂SiO_{2/2})_{b}(R⁹SiO_{3/2})_{c}(SiO_{4/2})_{d}(XO_{1/2})ₑ

(In the formula, each R⁹ is, independently, a halogen-substituted or unsubstituted monovalent hydrocarbon group, however, at least two R are alkenyl groups; each R¹⁰ is, independently, a halogen-substituted or unsubstituted monovalent hydrocarbon group or an epoxy group-containing organic group, however, at least one R¹⁰ is an epoxy group-containing organic group, and X is a hydrogen atom or an alkyl group; 0≤a≤1, 0≤b≤1, 0c<0.9, 0<d<0.5, and 0≤e≤0.4, a+b+c+d+e=1.0, and c+d>0).

In formula (II) above, the halogen-substituted or unsubstituted monovalent hydrocarbon groups R⁹ and R¹⁰ are preferably selected from C1-12 alkyl groups such as methyl groups, ethyl groups, propyl groups, isopropyl groups, butyl groups, isobutyl groups, tert-butyl groups, pentyl groups, neopentyl groups, hexyl groups, cyclohexyl groups, heptyl groups, octyl groups, nonyl groups, decyl groups, undecyl groups and dodecyl groups; C6-20 aryl groups such as phenyl groups, tolyl groups, xylyl groups and naphthyl groups; C2-12 alkenyl groups such as vinyl groups, allyl groups, butenyl groups, pentenyl groups, hexenyl groups, heptenyl groups, octenyl groups, nonenyl groups, decenyl groups, undecenyl groups and dodecenyl groups; and the above groups in which some or all of the hydrogen atoms are substituted with a halogen atom such as a fluorine atom, chlorine atom or bromine atom. R⁹ is preferably selected from C1-6 alkyl groups, especially a methyl group, C2-6 alkenyl groups, especially a vinyl group, and C6-20 aryl groups, especially a phenyl group.

Epoxy group-containing organic groups R¹⁰ in formula (II) above include, for example, glycidoxyalkyl groups such as a 2-glycidoxyethyl group, 3-glycidoxypropyl group and 4-glycidoxybutyl group; epoxycycloalkylalkyl groups such as a 2-(3,4-epoxycyclohexyl)ethyl group and 3-(3,4-epoxycyclohexyl)propyl group; and epoxyalkyl groups such as a 3,4-epoxybutyl group and 7,8-epoxyoctyl group, with a glycidoxyalkyl group being preferred and a 3-glycidoxypropyl group being particularly preferred. R¹⁰ is preferably selected from C1-6 alkyl groups, especially a methyl group, C2-6 alkenyl groups, especially a vinyl group, C6-20 aryl groups, especially a phenyl group, and a 3-glycidoxypropyl group. R¹⁰ is preferably selected from C1-6 alkyl groups, especially a methyl group, and a 3-glycidoxypropyl group.

X in formula (II) above is a hydrogen atom or an alkyl group. An X alkyl group is preferably a C1-3 alkyl group, and specific examples are a methyl group, ethyl group and propyl group.

In formula (II) above, with a+b+c+d+e=1.0 as a basis, a is preferably in the range 0.03≤a≤0.7, more preferably in the range 0.06≤a≤0.5, and especially in the range 0.09≤a≤0.3. In formula (II), b is preferably in the range 0.05≤b≤0.6, more preferably in the range 0.1≤b≤0.5, and especially in the range 0.15≤b≤0.4. In formula (II), c is preferably in the range 0.1≤c≤0.8, more preferably in the range 0.25≤c≤0.7, and especially in the range 0.4≤c≤0.6. In formula (II), d is preferably in the range 0≤d≤0.3, more preferably in the range 0≤d≤0.2, and even more preferably in the range 0≤d≤0.1. In formula (II), e is preferably in the range 0.05≤e≤0.4, more preferably in the range 0.1≤e≤0.3, and especially in the range 0.15≤e≤0.25.

In one embodiment, in formula (II) above, e/(a+b+c+d) is greater than 0.05. Preferably e/(a+b+c+d) is greater than 0.08, more preferably greater than 0.11, and even more preferably greater than 0.14. In addition, e/(a+b+c+d) is ordinarily less than 0.5, preferably less than 0.4, even more preferably smaller than 0.3, and particularly preferably smaller than 0.25.

In a preferred embodiment of the present invention, an epoxy group-containing resinous organopolysiloxane includes a siloxane unit in which c in formula (II) above is greater than 0, i.e., a siloxane unit represented by SiO_{3/2} (T unit). The epoxy group-containing resinous organopolysiloxane can include or not include, but preferably does not include, a siloxane unit represented by SiO_{4/2} (Q unit).

In a preferred embodiment of the present invention, an epoxy group-containing resinous organopolysiloxane contains an alkenyl group at the end of the molecule. The epoxy group-containing resinous organopolysiloxane preferably has an alkenyl group in a siloxane unit represented by SiO_{1/2} (M unit), and molecular side chains (i.e. siloxane units represented by SiO_{2/2} (D unit) and siloxane units represented by SiO_{3/2} (T unit)) can include or not include, but preferably do not include, an alkenyl group.

In a preferred embodiment, although there are no particular restrictions as to the quantity of alkenyl groups in the entirety of the silicon atom-bonded organic groups in the epoxy group-containing resinous organopolysiloxane, the quantity may be preferably ≥1 mol %, more preferably ≥3 mol %, even more preferably ≥5 mol %, and particularly preferably ≥8 mol %; in addition, the quantity can also be, for example, <30 mol %, preferably ≤20 mol %, and more preferably ≤15 mol %.

Although there are no particular restrictions as to the quantity of epoxy group-containing organic groups in the entirety of the silicon atom-bonded organic groups in the epoxy group-containing resinous organopolysiloxane, it is preferably ≥1 mol %, more preferably ≥5 mol %, even more preferably ≥10 mol %, and particularly preferably ≥15 mol %; in addition, the quantity can also be, for example, <40 mol %, preferably ≤30 mol %, and more preferably ≤25 mol %. It should be noted that the quantity of epoxy group-containing organic groups can be found, for example, by analyses such as Fourier-transform infrared spectroscopy (FT-IR) or nuclear magnetic resonance (NMR).

In a preferred embodiment of the present invention, an epoxy group-containing resinous organopolysiloxane includes aryl groups in the silicon atom-bonded organic groups. More specifically, in formula (I) above, at least one of R⁹ and R¹⁰ can be an aryl group. In a preferred embodiment of the present invention, an epoxy group-containing resinous organopolysiloxane contains a silicon atom-bonded aryl group on a molecular side chain, that is, a D unit or T unit, preferably a T unit. The epoxy group-containing resinous organopolysiloxane can include or not include, but preferably does not include, an aryl group at the end of the molecule, that is, on an M unit. It should be noted that aryl groups include C6-20 aryl groups, especially a phenyl group, tolyl group, xylyl group and naphthyl group.

When the epoxy group-containing resinous organopolysiloxane contains aryl groups, the content thereof (the mol % of aryl groups in the entirety of the silicon atom-bonded functional groups in the epoxy group-containing resinous organopolysiloxane) can be designed as desired, but may be preferably ≥15 mol %, more preferably ≥20 mol %, even more preferably ≥25 mol %, and particularly preferably ≥30 mol %; the content may be preferably ≤70 mol %, more preferably ≤60 mol %, even more preferably ≤50 mol %, and particularly preferably ≤40 mol %.

In a preferred embodiment of the present invention, an epoxy group-containing resinous organopolysiloxane includes a hydroxyl group and/or alkoxy group as a silicon atom-bonded organic group. Although there are no particular restrictions as to the content of hydroxyl groups and/or alkoxy groups in the entirety of the silicon atom-bonded organic groups in the epoxy group-containing resinous organopolysiloxane, the content is preferably ≥2 mol %, more preferably ≥5 mol %, and even more preferably ≥10 mol %; and the content is, for example, <30 mol %, preferably ≤20 mol %, and more preferably ≤15 mol %. It should be noted that the quantity of hydroxyl groups and/or alkoxy groups can be determined, for example, by analyses such as Fourier-transform infrared spectroscopy (FT-IR) or nuclear magnetic resonance (NMR).

Although there are no particular restrictions as to the viscosity of the epoxy group-containing resinous organopolysiloxane, it is, for example, in the range of 50 mPa·s to 20,000 mPa·s at 25° C. The viscosity at 25° C. of the organopolysiloxane components in this specification can be measured with a rotary viscometer in conformity with JIS K 7117-1.

Although there are no particular restrictions as to the quantity of epoxy group-containing resinous organopolysiloxane, when the curable silicone composition of the present invention includes epoxy group-containing resinous organopolysiloxane, the quantity that can be included, based on the total mass of alkenyl group-containing organopolysiloxane and organo-hydrogen polysiloxane, is preferably ≥0.1 mass %, more preferably ≥0.5 mass %, even more preferably ≥0.7 mass %; in addition, based on the total mass of alkenyl group-containing organopolysiloxane and organo-hydrogen polysiloxane, a quantity of <5 mass % can be included, more preferably ≤3 mass %, even more preferably ≤2 mass %, and particularly preferably ≤1.5 mass %.

(Alkenyl Group-Containing Cyclic Organopolysiloxane)

In one embodiment of the present invention, the curable silicone composition of the present invention can include alkenyl group-containing cyclic organosiloxane. The curable silicone composition of the present invention can include one type of alkenyl group-containing cyclic organopolysiloxane, or can include a combination of two or more types of alkenyl group-containing cyclic organopolysiloxanes.

Alkenyl group-containing cyclic organosiloxane is represented by the unit formula (III) below.

(R³₂SiO)ₙ Unit Formula (III):

In the formula, R³ are each independently halogen-substituted or unsubstituted monovalent hydrocarbon groups, however, in one molecule at least two R³ are alkenyl groups, and n is a number which yields a viscosity at 25° C. of <1000 mPa·s. Note that the viscosity can be measured with a rotary viscometer in conformity with JIS K 7117-1.

Examples of halogen-substituted or unsubstituted monovalent hydrocarbon groups as R³ in formula (III) above include C1-12 alkyl groups such as methyl groups, ethyl groups, propyl groups, isopropyl groups, butyl groups, isobutyl groups, tert-butyl groups, pentyl groups, neopentyl groups, hexyl groups, cyclohexyl groups, heptyl groups, octyl groups, nonyl groups, decyl groups, undecyl groups and dodecyl groups; C6-20 aryl groups such as phenyl groups, tolyl groups, xylyl groups and naphthyl groups; C7-20 aralkyl groups such as benzyl groups, phenethyl groups and phenylpropyl groups; C2-12 alkenyl groups such as vinyl groups, allyl groups, butenyl groups, pentenyl groups, hexenyl groups, heptenyl groups, octenyl groups, nonenyl groups, decenyl groups, undecenyl groups and dodecenyl groups; and the above groups in which some or all of the hydrogen atoms are substituted with a halogen atom such as a fluorine atom, chlorine atom or bromine atom. R³ can be a small quantity of hydroxyl groups or alkoxy groups such as methoxy groups or ethoxy groups within a range that will not detract from the objective of the present invention.

In formula (III) above, n is a number which yields a viscosity at 25° C. of <1000 mPa·s, for example, 4 to 15, preferably 4 to 10, and more preferably 4 to 8. It should be noted that the viscosity at 25° C. of the organopolysiloxane components in this specification can be measured with a rotary viscometer in conformity with JIS K 7117-1.

Although there are no particular restrictions as to the quantity of alkenyl groups in the entirety of the silicon atom-bonded organic groups in the alkenyl group-containing cyclic organopolysiloxane, the quantity is preferably ≥20 mol %, more preferably ≥30 mol %, and even more preferably ≥40 mol %; it is also, for example, ≤80 mol %, preferably ≤70 mol %, and more preferably ≤60 mol %.

When the curable silicone composition of the present invention includes alkenyl group-containing cyclic organopolysiloxane, the quantity that can be included, based on the total mass of alkenyl group-containing organopolysiloxane and organo-hydrogen polysiloxane, is preferably ≥1 mass %, more preferably ≥2 mass %, and even more preferably ≥3 mass %; in addition, based on the total mass of alkenyl group-containing organopolysiloxane and organo-hydrogen polysiloxane, the quantity that can be included is ≤15 mass %, more preferably ≤10 mass %, and even more preferably ≤5 mass %.

In a specific embodiment of the present invention, the curable silicone composition of the invention of this application includes, based on the total mass of alkenyl group-containing organopolysiloxane and organo-hydrogen polysiloxane, alkenyl group-containing cyclic organopolysiloxane at a content of ≤3 mass %, more preferably ≤2 mass %, and even more preferably ≤1.5 mass %. In addition, it is acceptable for the curable silicone composition of the present invention not to include alkenyl group-containing cyclic organopolysiloxane.

(Alkenyl Group-Containing Organopolysiloxane Comprising Solely M Units and Q Units)

In one embodiment of the present invention, the curable silicone composition of the present invention can include alkenyl group-containing cyclic organopolysiloxane comprising solely M units and Q units. A curable silicone composition of the present invention can include one type of alkenyl group-containing cyclic organopolysiloxane comprising solely M units and Q units, or it can include a combination of two or more types of alkenyl group-containing cyclic organopolysiloxanes comprising solely M units and Q units.

In the present specification, alkenyl group-containing organopolysiloxane comprising solely M units and Q units indicates organopolysiloxane comprising solely siloxane units represented by SiO_{1/2} (M units) and siloxane units represented by SiO_{4/2} (Q units). Preferably, the alkenyl group-containing organopolysiloxane comprising solely M units and Q units can be represented by unit formula (IV) below.

(R⁴₃SiO_{1/2})ₙ(SiO_{4/2})ₘ Unit formula (IV):

In the formula, R⁴ groups are each independently halogen-substituted or unsubstituted monovalent hydrocarbon groups, however, in one molecule at least two R⁴ are alkenyl groups, n is an integer in the range of 4 to 100, and m is an integer in the range of 1 to 100.

In formula (IV) above, halogen-substituted or unsubstituted monovalent hydrocarbons as R⁴ include the same groups as described for R³ in formula (III) above.

In formula (IV) above, n and m are preferably numbers which yield a viscosity at 25° C. of ≤1000 mPa·s; for example, n is 4 to 50, and preferably 4 to 16, and m is 1 to 50, and preferably 1 to 16.

In addition, in a specific embodiment, in formula (IV) above, n and m are preferably numbers which yield a viscosity at 25° C. of ≤1000 mPa·s; for example, n is 4 to 12, and preferably 4 to 8, and m is 1 to 4, preferably 1 to 3, and more preferably 1 to 2.

Although there are no particular restrictions as to the quantity of alkenyl group-containing organopolysiloxane comprising solely M units and Q units, the quantity is, for example, ≥10 mol %, preferably ≥20 mol %, and more preferably ≥30 mol %; it is also, for example, ≤60 mol %, preferably ≤50 mol %, and more preferably ≤40 mol %.

When the curable silicone composition of the present invention includes alkenyl group-containing organopolysiloxane comprising solely M units and Q units, the quantity that can be included, based on the total mass of alkenyl group-containing organopolysiloxane and organo-hydrogen polysiloxane, is preferably ≥1 mass %, more preferably ≥3 mass %, and even more preferably ≥5 mass %; in addition, based on the total mass of alkenyl group-containing organopolysiloxane and organo-hydrogen polysiloxane, the quantity that can be included is ≤20 mass %, more preferably ≤15 mass %, and even more preferably ≤10 mass %.

In aforementioned embodiment 2 of the present invention, the curable silicone composition includes alkenyl group-containing cyclic organopolysiloxane comprising solely M units and Q units. Although there are no particular restrictions as to the content of alkenyl group-containing organopolysiloxane comprising solely M units and Q units, the quantity that can be included, based on the total mass of alkenyl group-containing organopolysiloxane and organo-hydrogen polysiloxane, is preferably ≥1 mass %, more preferably ≥2 mass %, even more preferably ≥3 mass %, and particularly preferably ≥5 mass %; in addition, based on the total mass of alkenyl group-containing organopolysiloxane and organo-hydrogen polysiloxane, the quantity that can be included is ≤20 mass %, more preferably ≤15 mass %, and even more preferably ≤10 mass %.

In a specific embodiment of the present invention, in the curable silicone composition of the present invention, the content of resinous organopolysiloxane that contains alkenyl groups that are bonded to silicon atoms of siloxane units (D units), which are represented by SiO_{2/2}, is <50 mass % based on the total mass of alkenyl group-containing organopolysiloxane and organo-hydrogen polysiloxane. Preferably, the content of resinous organopolysiloxane that contains alkenyl groups that are bonded to silicon atoms of siloxane units (D units), represented by SiO_{2/2}, based on the total mass of alkenyl group-containing organopolysiloxane and organo-hydrogen polysiloxane, is <40 mass %, more preferably <30 mass %, even more preferably <20 mass %, preferentially <10 mass %, and particularly preferably <5 mass %. In addition, it is acceptable for the curable silicone composition of the present invention not to include resinous organopolysiloxane that contains alkenyl groups bonded to silicon atoms of siloxane units (D units), represented by SiO_{2/2}.

In addition, in a specific embodiment of the present invention, in the curable silicone composition of the present invention, the content of alkenyl group-containing resinous organopolysiloxane that includes siloxane units (D units), represented by SiO₂/2, is <50 mass % based on the total mass of alkenyl group-containing organopolysiloxane and organo-hydrogen polysiloxane. Preferably, the content of resinous organopolysiloxane that contains alkenyl groups that are bonded to silicon atoms of siloxane units (D units), which are represented by SiO_{2/2}, based on the total mass of alkenyl group-containing organopolysiloxane and organo-hydrogen polysiloxane, is <40 mass %, more preferably <30 mass %, even more preferably <20 mass %, preferentially <10 mass %, and particularly preferably <5 mass %.

(B) Resinous Organo-Hydrogen Polysiloxane which has at Least Two Silicon Atom-Bonded Hydrogen Atoms Per Molecule

Component (B) acts as a crosslinking agent in the curable silicone composition by means of a hydrosilylation curing reaction and is a resinous organo-hydrogen polysiloxane which has at least two silicon atom-bonded hydrogen atoms per molecule. The curable silicone composition of the present invention can include one type of resinous organo-hydrogen polysiloxane (B) or can include two or more types of resinous organo-hydrogen polysiloxanes (B).

Silicon atom-bonded groups other than silicon atom-bonded hydrogen atoms included in component (B) include halogen-substituted or unsubstituted monovalent hydrocarbon groups other than alkenyl groups, and examples include C1-12 alkyl groups such as methyl groups, ethyl groups, propyl groups, isopropyl groups, butyl groups, isobutyl groups, tert-butyl groups, pentyl groups, neopentyl groups, hexyl groups, cyclohexyl groups, heptyl groups, octyl groups, nonyl groups, decyl groups, undecyl groups and dodecyl groups; C6-20 aryl groups such as phenyl groups, tolyl groups, xylyl groups and naphthyl groups; C7-20 aralkyl groups such as benzyl groups, phenethyl groups and phenylpropyl groups; and the above groups in which some or all of the hydrogen atoms are substituted with a halogen atom such as a fluorine atom, chlorine atom or bromine atom. It should be noted that the silicon atoms in component (B) can have a small quantity of hydroxyl groups or alkoxy groups such as methoxy groups or ethoxy groups, within a range that will not detract from the purpose of the present invention. Silicon atom-bonded groups other than silicon atom-bonded hydrogen atoms in component (B) are preferably selected from C1-6 alkyl groups, especially methyl groups, and C6-20 aryl groups, especially phenyl groups.

In an embodiment of the present invention, resinous organo-hydrogen polysiloxane of component (B) may preferably be represented by average unit formula (V) below:

(R⁵₃SiO_{1/2})ₐ(R⁵₂SiO_{2/2})_{b}(R⁵SiO_{3/2})_{c}(SiO_{4/2})_{d}(XO_{1/2})ₑ Average Unit Formula (V):

In formula (V), each R⁵ is independently a hydrogen atom, or an identical or different halogen-substituted or unsubstituted monovalent hydrocarbon group other than an alkenyl group; however, in one molecule, at least two R⁵ are hydrogen atoms; 0≤a<1, 0≤b<1, 0≤c<0.9, 0≤d<0.7, and 0≤e<0.4, a+b+c+d=1.0, and c+d>0.

Halogen-substituted or unsubstituted monovalent hydrocarbon groups other than alkenyl groups as R⁵ in formula (V) above include C1-12 alkyl groups such as methyl groups, ethyl groups, propyl groups, isopropyl groups, butyl groups, isobutyl groups, tert-butyl groups, pentyl groups, neopentyl groups, hexyl groups, cyclohexyl groups, heptyl groups, octyl groups, nonyl groups, decyl groups, undecyl groups and dodecyl groups; C6-20 aryl groups such as phenyl groups, tolyl groups, xylyl groups and naphthyl groups; C7-20 aralkyl groups such as benzyl groups, phenethyl groups and phenylpropyl groups; and the above groups in which some or all of the hydrogen atoms are substituted with a halogen atom such as a fluorine atom, chlorine atom or bromine atom. R⁵ can be a small quantity of hydroxyl groups or alkoxy groups such as methoxy groups or ethoxy groups within a range that will not detract from the objective of the present invention. R⁵ is preferably selected from a hydrogen atom, C1-6 alkyl groups, especially methyl groups, or C6-20 aryl groups, especially phenyl groups.

X in formula (V) above is a hydrogen group or an alkyl group. An X alkyl group is preferably a C1-3 alkyl group, and specific examples are a methyl group, ethyl group and propyl group.

In formula (V) above, a is preferably in the range 0.1≤a≤0.9, more preferably in the range 0.3≤a≤0.8, and even more preferably in the range 0.5≤a≤0.7. In formula (V) above, b is preferably in the range 0≤b≤0.5, more preferably in the range 0≤b≤0.3, and especially in the range 0≤b≤0.1. In formula (V) above, c is preferably in the range 0≤c≤0.7, more preferably in the range 0≤c≤0.6, and especially in the range 0≤c≤0.5. In formula (V) above, d is preferably in the range 0≤d≤0.7, more preferably in the range 0≤d≤0.6, and especially in the range 0≤d≤0.5. In formula (V) above, e is preferably in the range 0≤e≤0.15, more preferably in the range 0≤e≤0.1, and especially in the range 0≤e≤0.05.

In a preferred embodiment of the present invention, in a resinous organo-hydrogen polysiloxane of component (B), c in formula (V) above is greater than 0, i.e. a T unit is included. A resinous organo-hydrogen polysiloxane of component (B) can include or not include, but preferably does not include, a Q unit.

In a preferred embodiment of the present invention, a resinous organo-hydrogen polysiloxane of component (B) contains a silicon atom-bonded hydrogen atom at the end of the molecule. The resinous organo-hydrogen polysiloxane of component (B) preferably has a silicon atom-bonded hydrogen atom in an M unit and can include or not include, but preferably does not include, a silicon atom-bonded hydrogen atom in a molecular-chain side chain (i.e., D units and T units).

In a preferred embodiment of the present invention, the resinous organo-hydrogen polysiloxane component (B) can include or not include an aryl group in the silicon atom-bonded organic groups. Examples of aryl groups include C6-20 aryl groups, for example phenyl groups, tolyl groups, xylyl groups and naphthyl groups; and phenyl groups are particularly preferred.

When a resinous organo-hydrogen polysiloxane of component (B) includes aryl groups, the content thereof (mol % of aryl groups in the entirety of silicon atom-bonded functional groups in the resinous organo-hydrogen polysiloxane) can be designed as desired, but it is ordinarily ≥1 mol %, preferably ≥5 mol %, more preferably ≥10 mol %, even more preferably ≥13 mol %, and particularly preferably ≥16 mol %; also, the content can be ≤50 mol %, and is preferably ≤40 mol %, more preferably ≤35 mol %, preferentially ≤30 mol %, and particularly preferably ≤25 mol %.

In one embodiment of the present invention, a resinous organopolysiloxane of component (B) can be an MQ resin comprising solely M units and Q units. In this embodiment, although the ratio of the number of moles of M units and Q units is not particularly restricted, the M unit:Q unit molar ratio can be, for example, within the range of 1:1 to 4:1, preferably within the range of 1.1:1 to 3:1, more preferably within the range of 1.2:1 to 2:1, and still more preferably within the range of 1.3:1 to 1:8:1.

Although there are no particular restrictions as to the viscosity of the resinous organopolysiloxane of component (B), the viscosity at 25° C. is, for example, in the range 10 mPa·s to 1000 mPa·s. It should be noted that the viscosity at 25° C. of the organopolysiloxane components in this specification can be measured with a rotary viscometer in conformity with JIS K 7117-1.

In addition, in an embodiment of the present invention, the number average molecular weight (Mn) of resinous organopolysiloxane of component (B) is preferably within the range of 500 to 3000, more preferably within the range of 750 to 2000, even more preferably within the range of 1000 to 2000, and particularly preferably within the range of 1000 to 1500.

Although not particularly restricted, the content of resinous organo-hydrogen polysiloxane of component (B), based on the total mass of alkenyl group-containing organopolysiloxane and organo-hydrogen polysiloxane, is preferably ≥0.1 mass %, more preferably ≥0.5 mass %, even more preferably ≥1 mass %, and particularly preferably ≥1.3 mass %. In addition, based on the total mass of alkenyl group-containing organopolysiloxane and organo-hydrogen polysiloxane, the content of component (B) is preferably ≤15 mass %, more preferably ≤10 mass %, even more preferably ≤8 mass %, and particularly preferably ≤5 mass %.

In addition, in a specific embodiment of the present invention, the content of resinous organo-hydrogen polysiloxane of component (B), based on the total mass of alkenyl group-containing organopolysiloxane and organo-hydrogen polysiloxane, is ≥0.1 mass %, more preferably ≥0.5 mass %, even more preferably ≥1 mass %, and particularly preferably ≥1.3 mass %; also, the content is ≤15 mass %, preferably ≤12 mass %, more preferably 59 mass %, and particularly preferably 56 mass %.

(Straight-Chain Organo-Hydrogen Polysiloxane)

In addition to the resinous organo-hydrogen polysiloxane component (B), the curable silicone composition of the present invention can contain a straight-chain organo-hydrogen polysiloxane as an organo-hydrogen polysiloxane. A curable silicone composition of the present invention can include one type of straight-chain organo-hydrogen polysiloxane, or it can or can include a combination of two or more types of straight-chain organo-hydrogen polysiloxanes.

The straight-chain organo-hydrogen polysiloxane may preferably be represented by:

R⁵₃SiO(R⁵₂SiO_{2/2})ₘSiR⁵₃ Average Structural Formula (VI):

(In formula (VI), each R⁵ is independently a hydrogen atom, or an identical or different halogen-substituted or unsubstituted monovalent hydrocarbon group other than an alkenyl group; however, in one molecule at least two R⁵ are hydrogen atoms, and m is 1 to 100).

The halogen-substituted or unsubstituted monovalent hydrocarbon groups other than alkenyl groups for R⁵ in formula (VI) above can be the same as in formula (V) above.

In formula (VI) above, m is preferably 1 to 50, more preferably 1 to 20, even more preferably 1 to 10, and particularly preferably 1 to 5.

In a preferred embodiment of the present invention, the straight-chain organo-hydrogen polysiloxane contains silicon atom-bonded hydrogen atoms at both ends of the molecular chain. The straight-chain organo-hydrogen polysiloxane has silicon atom-bonded hydrogen atoms in an M unit, and can include or not include, but preferably does not include, silicon atom-bonded hydrogen atoms in a D unit.

In a preferred embodiment of the present invention, the straight-chain organo-hydrogen polysiloxane contains silicon atom-bonded aryl groups. The straight-chain organo-hydrogen polysiloxane preferably contains silicon atom-bonded aryl groups in molecular-chain side chains. The straight-chain organopolysiloxane can include or not include, but preferably does not include, an aryl group at the end of the molecular chain.

In a more preferred embodiment of the present invention, the straight-chain organo-hydrogen polysiloxane includes a unit in which two aryl groups are bonded to a D unit silicon atom, i.e., a structural unit represented by Ar₂SiO_{2/2}.

In one embodiment of the present invention, when the straight-chain organo-hydrogen polysiloxane includes aryl groups, although there are no particular restrictions as to the content of aryl groups in the entirety of the silicon atom-bonded organic groups, the content is, for example, ≥10 mol % of the total silicon atom-bonded organic groups, preferably ≥15 mol %, and more preferably ≥20 mol %; the content can also be ≤50 mol % of the total silicon atom-bonded organic groups, preferably ≤40 mol %, and more preferably ≤30 mol %.

When the curable silicone composition of the present invention includes straight-chain organo-hydrogen polysiloxane, although there is no particular restriction on the content thereof, the quantity that can be included, based on the total mass of alkenyl group-containing organopolysiloxane and organo-hydrogen polysiloxane, is preferably ≥5 mass %, more preferably ≥10 mass %, and even more preferably ≥15 mass %, preferentially ≥20 mass %, and particularly preferably ≥25 mass %; in addition, based on the total mass of alkenyl group-containing organopolysiloxane and organo-hydrogen polysiloxane, the quantity that can be included is ≤40 mass %, more preferably ≤35 mass %, and even more preferably ≤30 mass %.

In addition, in one embodiment of the present invention, when the curable silicone composition of the present invention includes the straight-chain organo-hydrogen polysiloxane, the content thereof relative to the total mass of resinous alkenyl group-containing organopolysiloxane of component (A) may be preferably ≥25 mass %, more preferably ≥30 mass %, and even more preferably ≥35 mass %.

In an embodiment of the present invention, in the curable silicone composition of the present invention, the quantity of all organo-hydrogen polysiloxane components including the resinous organo-hydrogen polysiloxane of component (B), in relation to 1 mole of silicon atom-bonded alkenyl groups of all alkenyl group-containing organopolysiloxane components including the resinous alkenyl group-containing organopolysiloxane of component (A), is preferably a quantity at which silicon atom-bonded hydrogen atoms constitute 0.8 to 1.3 moles, more preferably a quantity at which silicon atom-bonded hydrogen atoms constitute 0.85 to 1.25 moles, and particularly preferably a quantity at which silicon atom-bonded hydrogen atoms constitute 0.9 to 1.2 moles. In other words, in the curable silicone composition of the present invention, a molar ratio (H/Vi) of hydrogen atoms to alkenyl groups originating from organopolysiloxane components may be preferably 0.8 to 1.3, more preferably 0.85 to 1.25, and especially 0.9 to 1.2.

In a specific embodiment of the present invention, in the curable silicone composition of the present invention, the molar ratio (H/Vi) of hydrogen atoms to alkenyl groups originating from organopolysiloxane components is 0.95 to 1.2, preferably 0.98 to 1.2, and more preferably 1.0 to 1.2.

In another embodiment of the present invention, although there is no particular restriction on the quantity of all organo-hydrogen polysiloxane components including the resinous organo-hydrogen polysiloxane of component (B), based on the total mass of alkenyl group-containing organopolysiloxane and organo-hydrogen polysiloxane, the quantity is preferably ≥5 mass %, more preferably ≥10 mass %, and even more preferably ≥15 mass %, preferentially ≥20 mass %, and particularly preferably ≥25 mass %; also, the quantity can be ≤45 mass %, preferably ≤40 mass %, and even more preferably ≤35 mass %.

(C) Additive Having a Wettability Improving Effect

The curable silicone composition of the present invention includes an additive as component (C) to improve the wettability of the curable silicone composition of the invention of this application. This additive is selected from a molecular-chain side chain polyether-modified organopolysiloxane, a phenol-modified organopolysiloxane, a terminal hydroxy group-containing dimethylpolysiloxane that does not include an aryl group, and a phenolic antioxidant, and also combinations thereof.

A single type of molecular-chain side chain polyether-modified organopolysiloxane (C-1) can be used, or a combination of two or more types can be used.

Examples of the molecular structure of the molecular-chain side chain polyether-modified organopolysiloxane of component (C-1) include straight chain, partially branched straight chain, branched chain, resinous, cyclic and three-dimensional network structure, but straight chain is preferred.

The molecular-chain side chain polyether-modified organopolysiloxane of component (C-1) may preferably be represented by average structural formula (VII) below:

R⁶₃SiO(R⁶₂SiO_{2/2})ₘ(R⁶R⁷SiO_{2/2})ₙSiR⁶₃ Average Structural Formula (VII):

(In formula (VII), each R⁶ is independently a halogen-substituted or unsubstituted monovalent hydrocarbon group other than an alkenyl group, R⁷ is a polyoxyalkylene group-containing organic group, m is a number in the range 0 to 1000, and n is a number in the range 1 to 1000).

Halogen-substituted or unsubstituted monovalent hydrocarbon groups other than alkenyl groups as R⁶ in formula (VII) above include C1-12 alkyl groups such as methyl groups, ethyl groups, propyl groups, isopropyl groups, butyl groups, isobutyl groups, tert-butyl groups, pentyl groups, neopentyl groups, hexyl groups, cyclohexyl groups, heptyl groups, octyl groups, nonyl groups, decyl groups, undecyl groups and dodecyl groups; C6-20 aryl groups such as phenyl groups, tolyl groups, xylyl groups and naphthyl groups; C7-20 aralkyl groups such as benzyl groups, phenethyl groups and phenylpropyl groups; and the above groups in which some or all of the hydrogen atoms are substituted with a halogen atom such as a fluorine atom, chlorine atom or bromine atom. R⁶ can be a small quantity of hydroxyl groups or alkoxy groups such as methoxy groups or ethoxy groups within a range that will not detract from the objective of the present invention. R⁶ is preferably selected from C1-6 alkyl groups, especially methyl groups, or C6-20 aryl groups, especially phenyl groups.

Although there are no particular restrictions as to the structure of oxyalkylene groups in the polyoxyalkylene group-containing organic group R⁷ in formula (VII), examples of structures include two or more oxyethylene units, oxypropylene units, or oxybutylene units, or a combination thereof. The polyoxyalkylene group-containing organic group preferably includes ≥4 oxyalkylene units, more preferably ≥6 oxyalkylene units, and even more preferably ≥8 oxyalkylene units; also, the polyoxyalkylene group-containing organic group includes ≤100 oxyalkylene units, preferably ≤60 oxyalkylene units, more preferably ≤40 oxyalkylene units, and even more preferably ≤20 oxyalkylene units.

Note that the alkylene section that constitutes an oxypropylene unit or oxybutylene unit may be a straight-chain alkylene group, or it may be a branched isoalkylene group such as an isopropylene group or isobutylene group.

The polyoxyalkylene group-containing organic group R⁷ in formula (VII) above may preferably be represented by formula (1) below:

—R⁸—O—(C₂H₄O)ₜ₁(C₃H₆O)ₜ₂(C₄H₈O)ₜ₃—Y Formula (1):

Here, R⁸ is a silicon atom-bonded C1-6, preferably C1-3, divalent organic group; t1, t2, and t3 are numbers satisfying 0≤t1≤60, 0≤t2≤50, 0≤t3≤50, and 2≤t1+t2+t3≤110; and Y is a group selected from a hydrogen atom, C1-4 alkyl group, and COCH₃ group.

In formula (1), R⁸ includes, for example, alkylene groups, alkenylene groups, arylene groups, and the like, and more specific examples include methylene groups, ethylene groups, propylene groups, butylene groups, pentylene groups, hexylene groups, and phenylene groups.

In formula (1), Y is a terminal group for the polyoxyalkylene structure, and is selected from a hydrogen atom, C1-4 alkyl group, and COCH₃ group; Y may preferably be a hydrogen atom or a methyl group.

In formula (1), t1, t2, and t3 are the numbers of oxyethylene units, oxypropylene units, and oxybutylene units that constitute the polyoxyalkylene structure, and they are numbers that satisfy 2<t1+t2+t3<110, preferably 6<t1+t2+t3<50, and more preferably 8<t1+t2+t3<20.

In an embodiment of the present invention, in formula (1), t1 is a number ≥2, preferably ≥4, more preferably ≥6, and even more preferably ≥8, and it is ≤50, preferably ≤30, more preferably ≤20, and even more preferably ≤15. In an embodiment of the present invention, in formula (1), t2 is a number ≥0 and ≤50, preferably ≤30, more preferably ≤10, even more preferably ≤3, and 0 is also acceptable. In an embodiment of the present invention, in formula (1), t3 is a number ≥0 and ≤50, preferably ≤30, more preferably ≤10, even more preferably ≤3, and 0 is also acceptable.

In formula (VII), n and m are degrees of siloxane polymerization of straight-chain molecular-chain side chain polyether-modified organopolysiloxane; m is a number in the range 0 to 1000, and n is a number in the range 1 to 1000. Preferably, m is a number in a range that it is ≥1 and ≤500, more preferably ≤150, even more preferably ≤100, preferentially ≤50, and particularly preferably ≤10. Preferably, n is a number in a range that is ≤500, more preferably ≤150, even more preferably ≤100, preferentially ≤50, and particularly preferably ≤20.

In a preferred embodiment, the molecular-chain side chain polyether-modified organopolysiloxane of component (C) is a straight chain and has a polyoxyalkylene group selected from polyoxyethylene (POE) and polyoxypropylene (POP). The molecular-chain side chain polyether-modified organopolysiloxane of component (C) may preferably be represented by general formula (2) below:

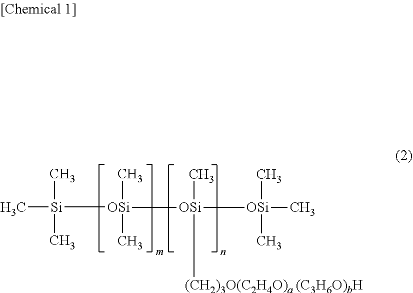

In formula (2) above, m is 1 to 1000, preferably 5 to 500, and n is 1 to 40. Additionally, m:n is preferably 200:1 to 1:1. Furthermore, a is 5 to 50, preferably 8 to 30, and more preferably 10 to 20. b is 0 to 50, preferably 0 to 10, and 0 is acceptable. In other words, the polyether-modified organopolysiloxane of component (C) includes polyoxyethylene units and may comprise solely polyoxyethylene units.

In a preferred embodiment, the molecular-chain side chain polyether-modified organopolysiloxane is selected from molecules in which HLB(Si) is 4 to 15, preferably 7 to 15, more preferably 9 to 15, and even more preferably 11 to 15. HLB(Si) mentioned here is a value determined by the following calculation formula.

$$\frac{Molecular weight of polyoxyalkylene group}{Molecular weight} \times 20 \qquad [ Calculation 1 ]$$

Preferred specific examples of the molecular-chain side chain polyether-modified organopolysiloxane of component (C-1) include PEG/PPG-19/19 dimethicone, PEG/PPG-30/10 dimethicone, PEG-12 dimethicone, PEG-11 methylether dimethicone, and the like.

Specific examples of commercial products of molecular-chain side chain polyether-modified organopolysiloxane of component (C-1) include the following:
Trade name BYI1-030 (manufactured by Dow Corning Toray Co. Ltd., PEG/PPG-19/19 dimethicone (HLB(Si)=7.7),
Trade name SH3773M (manufactured by Dow Corning Toray Co. Ltd., PEG-12 dimethicone (HLB(Si)=7.7),
Trade name BY25-339 (manufactured by Dow Corning Toray Co. Ltd., PEG/PPG-30/10 dimethicone (HLB(Si)=12.2),
Trade name KF6011 (manufactured by Shin-Etsu Chemical Co., Ltd., PEG-11 methylether dimethicone (HLB(Si)=14.5).

Although not particularly restricted, the number-average molecular weight of molecular-chain side chain polyether-modified organopolysiloxane of component (C-1) is suitably in the range of 3000 to 60,000 and particularly suitably 3000 to 40,000.

A single type of phenol-modified organopolysiloxane (C-2) can be used, or a combination of two or more types can be used.

Examples of the molecular structure of phenol-modified organopolysiloxane (C-2) include straight chain, partially branched straight chain, branched chain, resinous, cyclic, and three-dimensional network structure, but straight chain is preferred.

The phenol-modified organopolysiloxane of component (C-2) may preferably be represented by average structural formula (VIII) below:

R⁸₃SiO(R₂SiO_{2/2})ₘSiR⁸₃ Average Structural Formula (VIII):

(In formula (VIII), each R⁸ is independently a halogen-substituted or unsubstituted monovalent hydrocarbon group other than an alkenyl group, or is a phenol group-containing organic group, however, at least one R⁸ is a phenol group-containing organic group, and m is a number in the range 1 to 1000).

The halogen-substituted or unsubstituted monovalent hydrocarbon groups other than an alkenyl group of R⁸ in formula (VIII) can be the same as R⁶ in formula (VII) above.

Although the phenol group-containing organic group of R⁸ in formula (VIII) is not particularly restricted, it can be represented by formula (3) below:

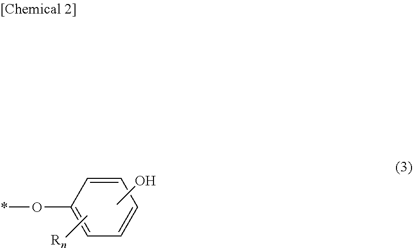

In formula (3), R is a C1-6 alkyl group, and particularly a C1-4 alkyl group; n is 1 to 4 and is preferably 1; and * represents the bonding part with a silicon atom to which a phenol group-containing organic group is bound.

The phenol group-containing organic group of the phenol-modified organopolysiloxane of component (C-2) may be included at the end of the molecule, and may be included in a molecular side chain. In a preferred embodiment, the phenol group-containing organic group is included at the end of the molecular chain of the phenol-modified organopolysiloxane, and particularly at both ends of the molecular chain.

Specific examples of commercial products of the phenol-modified organopolysiloxane of component (C-2) include trade name KF2201 (manufactured by Shin-Etsu Chemical Co., Ltd.).

Although there are no particular restrictions as to the viscosity of the phenol-modified organopolysiloxane of component (C-2), the viscosity at 25° C. is, for example, in the range of 1×10⁴ to 1×10⁸ St, and particularly suitably 1×10⁵ to 1×10⁷ St.

Although there are no particular restrictions as to the refractive index of the phenol-modified organopolysiloxane of component (C-2), it is, for example, within the range 1.35 to 1.5, preferably within the range 1.38 to 1.47, and more preferably within the range 1.40 to 1.45.

A single type of (C-3) terminal hydroxy group-containing dimethylpolysiloxane that does not include an aryl group can be used, or a combination of two or more types can be used.

Examples of the molecular structure of the terminal hydroxy group-containing dimethylpolysiloxane that does not include an aryl group of component (C-3) include straight chain, partially branched straight chain, branched chain, resinous, cyclic, and three-dimensional network structure, but straight chain is preferred.

The terminal hydroxy group-containing dimethylpolysiloxane that does not include an aryl group of component (C-3) is preferably a straight chain and includes a hydroxy group at both ends of the molecular chain. Accordingly, the terminal hydroxy group-containing dimethylpolysiloxane that does not include an aryl group of component (C-3) may be represented by average structural formula (IX) below:

HOR⁹₂SiO(R⁹₂SiO_{2/2})ₘSiR⁹₂OH Average Structural Formula (IX):

(In formula (IX), each R⁹ is independently a halogen-substituted or unsubstituted monovalent hydrocarbon group other than an alkenyl group or an aryl group, OH is a hydroxyl group, and m is a number in the range 1 to 1000).

Halogen-substituted or unsubstituted monovalent hydrocarbon groups other than an alkenyl group or an aryl group as R⁹ in formula (IX) above preferably include C1-12 alkyl groups such as methyl groups, ethyl groups, propyl groups, isopropyl groups, butyl groups, isobutyl groups, tert-butyl groups, pentyl groups, neopentyl groups, hexyl groups, cyclohexyl groups, heptyl groups, octyl groups, nonyl groups, decyl groups, undecyl groups and dodecyl groups, and the above groups in which some or all of the hydrogen atoms are substituted with a halogen atom such as a fluorine atom, chlorine atom or bromine atom. R⁹ can be a small quantity of hydroxyl groups or alkoxy groups such as methoxy groups or ethoxy groups within a range that will not detract from the objective of the present invention. R⁹ is preferably selected from C1-6 alkyl groups, especially a methyl group.

In formula (IX), m is preferably 1 to 100, more preferably 1 to 50, even more preferably 1 to 20, and particularly preferably 1 to 12.

Although there are no particular restrictions as to the viscosity of the terminal hydroxy group-containing dimethylpolysiloxane that does not include an aryl group of component (C-3), the viscosity at 25° C. is, for example, in the range of 0.1 to 1000 St, and particularly suitably 0.1 to 100 St.

A single type of phenolic antioxidant (C-4) can be used, or a combination of two or more types can be used.

The phenolic antioxidant (C-4) is preferably selected from conventionally known phenolic primary antioxidants. A phenolic antioxidant that has excellent compatibility with the organopolysiloxane components of the invention of this application, particularly with the aryl-containing organopolysiloxane of component (A), is suitably used for the phenolic antioxidant (C-4). Such phenolic antioxidants preferably include alkylphenols, and specific examples thereof include: 2,6-di-tert-butyl-p-cresol (BHT), 2-t-butyl-4,6-dimethylphenol, 2,6-di-t-butyl-4-ethylphenol, 2,6-di-t-butyl-4-n-butylphenol, 2,6-di-t-butyl-4-isobutylphenol, 2,6-dicyclopentyl-4-methylphenol, 2-(1-methylcyclohexyl)-4,6-dimethylphenol, 2,6-dioctadecyl-4-methylphenol, 2,4,6-tricyclohexylphenol, 2,6-di-t-butyl-4-methoxymethylphenol, nonylphenols having straight or branched side chains (e.g., 2,6-di-nonyl-4-methylphenol), 2,4-dimethyl-6-(1′-methylundeca-1′-yl)phenol, 2,4-dimethyl-6-(1′-methylheptadeca-1′-yl)phenol, 2,4-dimethyl-6-(1′-methyltrideca-1′-yl)phenol and mixtures thereof, 4-hydroxylaurylanilide, 4-hydroxystearylanilide, and octyl N-(3,5-di-t-butyl-4-hydroxyphenyl)carbamate, 2,2′-methylenebis(6-t-butyl-4-methyphenol), 2,2′-methylenebis(6-t-butyl-4-ethylphenol), 2,2′-methylenebis[4-methyl-6-(1-methylcyclohexyl)phenol], 2,2′-methylenebis(4-methyl-6-cyclohexylphenol), 2,2′-methylenebis(6-nonyl-4-methylphenol), 2,2′-methylenebis(4,6-di-t-butylphenol), 2,2′-ethylidenebis(4,6-di-t-butylphenol), 2,2′-ethylidenebis(6-t-butyl-4-isobutylphenol), 2,2′-methylenebis[6-(α-methylbenzyl)-4-nonylphenol], 2,2′-methylenebis[6-(α,α-dimethylbenzyl)-4-nonylphenol], 4,4′-methylenebis(2,6-di-t-butylphenol), 4,4′-methylenebis(6-t-butyl-2-methylphenol), 1,1-bis(5-t-butyl-4-hydroxy-2-methylphenyl)butane, 2,6-bis(3-t-butyl-5-methyl-2-hydroxybenzyl)-4-methylphenol, 1,1,3-tris(5-t-butyl-4-hydroxy-2-methylphenyl)butane, 1,1-bis(5-t-butyl-4-hydroxy-2-methylphenyl)-3-n-dodecylmercaptobutane, ethylene glycol bis[3,3-bis(3′-t-butyl-4′-hydroxyphenyl)butyrate], bis(3-t-butyl-4-hydroxy-5-methyl-phenyl)dicyclopentadiene, bis[2-(3′-t-butyl-2′-hydroxy-5′-methylbenzyl)-6-t-butyl-4-methylphenyl]terephthalate, 1,1-bis(3,5-dimethyl-2-hydroxyphenyl)butane, 2,2-bis(3,5-di-t-butyl-4-hydroxyphenyl)propane, 2,2-bis(5-t-butyl-4-hydroxy-2-methylphenyl)-4-n-dodecylmercaptobutane, and 1,1,5,5-tetra(5-t-butyl-4-hydroxy-2-methylphenyl)pentane, and the like. From the viewpoint of compatibility with the aryl-containing organopolysiloxane of component (A), 2,6-di-tert-butyl-p-cresol (BHT) is particularly preferable.

Although the content of additive having a wettability improving effect of component (C) is not particularly restricted, based on the total mass of alkenyl group-containing organopolysiloxane and organo-hydrogen polysiloxane, the content is preferably ≥0.01 mass %, more preferably ≥0.02 mass %, even more preferably ≥0.03 mass %, and particularly preferably ≥0.04 mass %. In addition, based on the total mass of alkenyl group-containing organopolysiloxane and organo-hydrogen polysiloxane, the content of component (C) is preferably ≤5 mass %, more preferably ≤3 mass %, even more preferably ≤2 mass %, and particularly preferably ≤1.5 mass %.

(D) Curing Catalyst

The curing catalyst of component (D) is a hydrosilylation reaction curing catalyst for promoting curing of a curable silicone composition of the present invention. Examples of such a component (D) include platinum-based catalysts such as chloroplatinic acid, an alcoholic solution of chloroplatinic acid, platinum-olefin complex, a complex of platinum and 1,3-divinyl-1,1,3,3-tetramethyldisiloxane, and powders supporting platinum; palladium-based catalysts such as tetrakis(triphenylphosphine)palladium, palladium black and mixtures with triphenylphosphine; and also rhodium-based catalysts; platinum-based catalysts are particularly preferable.

The blending quantity of component (D) is a catalytic amount; more specifically, when a platinum-based catalyst is used as component (D), the quantity of platinum atoms in the total mass of the curable silicone composition of the present invention is preferably ≥0.01 ppm, more preferably ≥0.1 ppm, and even more preferably ≥1 ppm, and the quantity of platinum atoms in the total mass of the curable silicone composition of the present invention is also preferably ≤20 ppm, more preferably ≤15 ppm, and even more preferably ≤12 ppm.

In a specific embodiment of the present invention, the blending quantity of component (D) when a platinum-based catalyst is used as component (D) is such that the quantity of platinum atoms relative to the total mass of the curable silicone composition of the present invention is <10 ppm, preferably <9 ppm, more preferably <8 ppm, and even more preferably <7 ppm.

The curable silicone composition of the present invention can include optional components within a range that will not detract from the objective of the present invention. Examples of such optional components include acetylene compounds, organophosphorus compounds, vinyl group-containing siloxane compounds, inorganic fillers such as powdered quartz, silica, titanium oxide, magnesium carbonate, zinc oxide, iron oxide and diatomite, inorganic fillers where the surface of the inorganic filler has undergone a water repellency treatment with an organosilicon compound, hydrosilylation reaction inhibitors, organopolysiloxanes which do not contain silicon atom-bonded hydrogen atoms or silicon atom-bonded alkenyl groups, tackifiers, agents conferring heat-resistance, agents conferring cold-resistance, thermally conductive fillers, flame retardants, thixotropic agents, phosphors, and solvents. Note that when the curable silicone composition includes a tackifier, the content thereof to 100 parts by mass of organopolysiloxane components may be a quantity of ≤5 parts by mass, more preferably ≤3 parts by mass, even more preferably ≤2 parts by mass, and particularly preferably ≤1.5 parts by mass.

Hydrosilylation reaction inhibitors are components for inhibiting a hydrosilylation reaction of the curable silicone composition. Examples of such curing reaction inhibitors include alkyne alcohols such as 2-methyl-3-butyn-2-ol, 3,5-dimethyl-1-hexyn-3-ol, 2-phenyl-3-butyn-2-ol, and 1-ethynyl-1-cyclohexanol; enyne compounds such as 3-methyl-3-penten-1-yne and 3,5-dimethyl-3-hexen-1-yne; alkenyl group-containing low-molecular-weight siloxanes such as tetramethyl-tetravinyl-cyclotetrasiloxane and tetramethyl-tetrahexenyl-cyclotetrasiloxane; and alkynyloxysilanes such as methyl-tris(1,1-dimethylpropynyloxy)silane and vinyl-tris(1,1-dimethylpropynyloxy)silane. The hydrosilylation reaction inhibitor is preferably selected from alkyl alcohols, and is particularly preferably 2-methyl-3-butyn-2-ol or 1-ethynyl-1-cyclohexanol. The addition quantity of reaction inhibitor is usually 0.001 to 5 parts by mass, relative to 100 parts by mass of organopolysiloxane components.

In an embodiment of the present invention, when the curable silicone composition includes 2-methyl-3-butyn-2-ol as the reaction inhibitor, the content thereof relative to 100 parts by mass of organopolysiloxane components is preferably ≥0.5 parts by mass and more preferably ≥1 part by mass; it is usually ≤5 parts by mass.

In another embodiment of the present invention, when the curable silicone composition includes 1-ethynyl-1-cyclohexanol as the reaction inhibitor, the content thereof relative to 100 parts by mass of organopolysiloxane components is preferably ≥0.01 parts by mass and more preferably ≥0.05 parts by mass; it is usually ≤2 parts by mass.

In aforementioned embodiment 2 of the present invention, the curable silicone composition includes ethynylcyclohexanol as the reaction inhibitor. The ethynylcyclohexanol may be 1-ethynyl-1-cyclohexanol or 1-ethynyl-2-cyclohexanol, but 1-ethynyl-1-cyclohexanol is preferred. The content thereof relative to 100 parts by mass of organopolysiloxane components is preferably ≥0.01 parts by mass and more preferably ≥0.05 parts by mass; it is usually ≤2 parts by mass and is preferably ≤1 part by mass.

Although there are no particular restrictions as to the viscosity of the curable silicone composition of the present invention, the viscosity at 25° C. is preferably in the range of 100 mPa·s to 700 mPa·s, and more preferably in the range of 300 mPa·s to 600 mPa·s. Viscosity can be determined with a type B rotary viscometer (MCR-302, manufactured by Anton Paar Co.) in accordance with the method described in JIS K 7117-1:1999.

In a specific embodiment of the present invention, the viscosity of the curable silicone composition at 25° C. is ≤1000 mPa·s, preferably in the range of 200 mPa·s to 700 mPa·s, and more preferably in the range of 300 mPa·s to 650 mPa·s.

After hardening, the curable silicone composition of the present invention can form a cured product with high hardness. The cured product obtained by hardening of the curable silicone composition of the present invention preferably has a type D durometer hardness at 25° C. of ≥D60. It should be noted that this type D durometer hardness can be determined with a type D durometer in accordance with JIS K 6253-1997 “Hardness testing methods for vulcanized rubber and thermoplastic rubber”.

In a specific embodiment of the present invention, a cured product obtained by hardening of the curable silicone composition of the present invention preferably has a type D durometer hardness at 25° C. of ≥D55.

After hardening, the curable silicone composition of the present invention can form a cured product having good transparency. More specifically, the cured product of the curable silicone composition of the present invention can retain a high degree of transparency with little yellowing even after being heated. For example, a 2 mm thick cured product of a curable silicone composition of the present invention preferably has a light transmittance of ≥95% for light of wavelength 400 nm to wavelength 700 nm after being held at 150° C. for 8 hours. It should be noted that the light transmittance of the cured product of the curable silicone composition of the present invention can be determined, for example, by measuring the cured product using a spectrophotometer.

The curable silicone composition of the present invention can be prepared by mixing each of the components. The process for mixing the components can be a conventionally known process, without any particular restriction, but simple stirring will ordinarily give a uniform mixture. In addition, when solid components such as inorganic fillers are included as optional components, mixing by using a mixing device is more preferred. There is no particular restriction as to such a mixing device, and examples include a single-screw or twin-screw continuous mixer, double rolls, a Ross mixer, a Hobart mixer, a dental mixer, a planetary mixer, a kneader mixer and a Henschel mixer, etc.

[Encapsulant]

The present invention also relates to an encapsulant for semiconductors comprising the curable silicone composition of the present invention. The present invention also relates to a sealing material obtained by curing the encapsulant of the present invention. In other words, a sealing material of the present invention includes a cured product of the curable silicone composition of the present invention.

There is no particular restriction as to the shape of the sealing material of the present invention, but it is preferably in the form of a dome or in the form of a sheet. There is no restriction as to the semiconductor encapsulated by the encapsulant, sealing material or film of the present invention, and examples include semiconductors such as SiC and GaN, and especially power semiconductors or optical semiconductors such as light-emitting diodes.

With the encapsulant of the present invention, a cured product which has excellent surface smoothness, is transparent, and has high hardness can be formed because the curable silicone composition of the present invention is used.

[Optical Semiconductor Element]

The present invention also relates to an optical semiconductor element which is encapsulated by the cured product of the encapsulant of the present invention. In other words, the optical semiconductor element of the present invention comprises the cured product of the encapsulant of the present invention. The optical semiconductor element can be, for example, a light-emitting diode (LED), semiconductor laser, photodiode, phototransistor, solid-state imaging element, photocoupler light-emitting element and light-receiving element; it is particularly preferably a light-emitting diode (LED).

A light-emitting diode (LED) emits light from above, below, left and right of the optical semiconductor element, and hence, the parts constituting the light-emitting diode (LED) preferably do not absorb light, and are preferably materials with high light transmittance or high reflectance. Therefore, the substrate on which the optical semiconductor element is mounted is also preferably a material with high light transmittance or high reflectance. Such substrates on which optical semiconductor elements are mounted include, for example: electrically conductive metals such as silver, gold and copper; electrically non-conductive metals such as aluminum and nickel; thermoplastic resins such as PPA and LCP mixed with a white pigment; thermosetting resins such as epoxy resins, BT resins, polyimide resins, and silicone resins containing a white pigment; and ceramics such as alumina and alumina nitride.

### EXAMPLES

The curable silicone composition of the present invention will be described in detail below by means of practical examples and comparative examples.

The different components were mixed to give the compositions shown in the tables (parts by mass) to prepare curable silicone compositions. It should be noted below that Me represents a methyl group, Vi represents a vinyl group, Ph represents a phenyl group, Ep represents a 3-glycidoxypropyl group, PE represents an organic functional group that includes a polyether structure, and PH represents an organic functional group that includes a phenol structure. In addition, in the tables, the structure of the organopolysiloxane components is presented in a simplified form, and functional groups other than Me in the M, D or T units are shown in parentheses. Also, H/Vi shows the molar ratio of silicon atom-bonded hydrogen atoms (H) and vinyl groups (Vi) in the organopolysiloxane component.

(Component a: Alkenyl Group-Containing Organopolysiloxane)
Component a-1: Resinous alkenyl group-containing organopolysiloxane represented by average unit formula (ViMe₂SiO_{1/2})₂₅ (PhSiO_{3/2})₇₅
Component a-2: Epoxy group-containing resinous organopolysiloxane represented by average unit formula (ViMe₂SiO_{1/2})₁₃(EpMeSiO_{2/2})₂₄ (PhSiO_{3/2})₄₆(OMe)₁7
Component a-3: Cyclic alkenyl group-containing organopolysiloxane represented by average structural formula (ViMeSiO)₄
Component a-4: Resinous alkenyl group-containing organopolysiloxane represented by average structural formula (ViMe₂SiO)₄Si
Component a-5: Resinous alkenyl group-containing organopolysiloxane represented by average unit formula (Me₃SiO_{1/2})₅(ViMe₂SiO_{1/2})₁₇(MeSiO_{3/2})₃₉ (PhSiO_{3/2})₃₉
Component a-6: Resinous alkenyl group-containing organopolysiloxane represented by average unit formula (ViMeSiO_{2/2})₂₅(Ph₂SiO_{2/2})₃₀ (PhSiO_{3/2})₄₅

(Component b: Organo-Hydrogen Polysiloxane)
Component b-1: Resinous organo-hydrogen polysiloxane represented by average unit formula (HMe₂SiO_{1/2})₆₀ (PhSiO_{3/2})₄₀
Component b-2: Straight-chain organo-hydrogen polysiloxane represented by average structural formula HMe₂SiO(Ph₂SiO)SiMe₂H
Component b-3: Resinous organo-hydrogen polysiloxane represented by average structural formula (HMe₂SiO_{1/2})₆₂(SiO_{4/2})₃₈

(Component c: Additive Having a Wettability Improving Effect)
Component c-1: Molecular-chain side chain polyether-modified organopolysiloxane represented by average structural formula Me₃SiO(Me₂SiO)ₙ(Me(PE)SiO)ₘSiMe₃ (HLB value: 12.7)
Component c-2: Molecular chain terminated phenol-modified organopolysiloxane represented by average structural formula PHMe₂SiO(Me₂SiO)ₘSiPHMe₂ (refractive index: 1.42)
Component c-3: Hydroxy terminated polydimethylsiloxane (HO(Me₂SiO)ₙH: n=12, viscosity 50 cSt
Component c-4: BHT(2,6-di-tert-butyl-p-cresol)
Component c′-1: Terminal hydroxy group phenyl silicone oil represented by average structural formula HOMe₂SiO(Ph₂SiO)SiMe₂OH
Component c′-2: Epoxy group-containing resinous organopolysiloxane represented by average unit formula (EpSiO_{3/2})(ViMeSiO_{2/2})(Me₂SiO_{2/2})
Component c′-3: Organopolysiloxane represented by average structural formula (ViMe₂SiO)(Me₂SiO)₃Si(OMe)₃
Component c′-4: 1,6-Bis(trimethoxysilyl)hexane
Component c′-5: Methyltrimethoxysilane
Component c′-6: Phenyltrimethoxysilane
Component c′-7: (3-Glycidoxypropyl)trimethoxysilane
Component c′-8: Methacryltrimethoxysilane
Component c′-9: Propyltrimethoxysilane
Component c′-10: 2-(3,4-Epoxycyclohexyl)ethyltrimethoxysilane
Component c′-11: Vinyltrimethoxysilane
Component c′-12: Propylene glycol monomethyl ether acetate (PGMEA) solvent
Component c′-13: PP solvent
Component c′-14: 1-Butyl-3-methylimidazolium hexafluorophosphate
Component c′-15: Epoxy-modified silicone oil
Component c′-16: Organopolysiloxane polyether-modified at both ends of the molecular chain, represented by average structural formula (PEG)Me₂SiO(Me₂SiO)₂SiMe₂(PEG)

(Component d: Curing Catalyst)
Component d: Complex of platinum and 1,3-divinyl-1,1,3,3-tetramethyldisiloxane with a platinum concentration of 4.0 mass %

(Component e: Hydrosilylation Reaction Inhibitor)
Component e-1: 2-Methyl-3-butyn-2-ol
Component e-2: 1-Ethynyl-1-cyclohexanol
Component e-3: 2-phenyl-3-butyn-2-ol
Component e-4: 3,5-dimethyl-1-hexyn-3-ol

### Practical Examples 1 to 14 and Comparative Examples 1 to 25

The different components were mixed to give the compositions shown in the tables below (parts by mass) to prepare curable silicone compositions. Note that the quantity of curing catalyst of component d is presented as the quantity of platinum atoms (ppm) included in component d. The evaluations below were carried out, and the results are summarized in the tables below.

[Viscosity]

The viscosity of the curable silicone compositions was measured at 25° C. and 20 s⁻¹ using a viscoelasticity measurement apparatus (MCR-302, manufactured by Anton Paar Co.) in accordance with the method described in JIS K 7117-1:1999.

[Hardness of the Cured Product]

The curable silicone compositions obtained were heated at 90° C. for 20 minutes to prepare 10-mm-thick cured products. The hardness of the cured products was measured with a type D durometer as specified in JIS K 7215-1986 “Testing Methods for Durometer Hardness of Plastics”.

[Light Transmittance of the Cured Product]

The curable silicone compositions obtained (2 mm thickness) were heat treated at 150° C. for 8 hours to produce test pieces. The light transmittance of these test pieces was measured at 25° C. using a self-recording spectrophotometer capable of measuring at any wavelength in the visible light range (wavelength 400 nm to 700 nm). Transmittance of 450 nm light of ≥95% was considered “OK”.

[Wettability]

Approximately 2 mg of obtained curable silicone composition was applied onto a polycarbonate sheet (commercial product name: Iupilon Sheet, FE-2000, manufactured by Mitsubishi Gas Chemical Co., Inc.) by dispenser molding, the diameter of the applied material was measured immediately after application and measured again after the material had been left to stand at 25° C. for 30 minutes, and when the ratio of the diameter of applied material after being allowed to stand at 25° C. for 30 minutes to the diameter of the applied material immediately after application (diameter of applied material after being allowed to stand at 25° C. for 30 minutes/diameter of applied material immediately after application) was <2.0, the result was considered “OK”, and when this ratio was ≥2.0, the result was considered “NG”.

[Curability]

The curable silicone compositions obtained were measured using a curability tester (moving die rheometer (MDR)) at a temperature of 90° C., and when the time from immediately after measurement until saturation torque was reached was <5 minutes, the result was considered “OK”, and when the time was ≥5 minutes, the result was considered “NG”.

[Pot Life]

The viscosity was measured after the curable silicone compositions obtained had been held at a temperature of 40° C. for 4 hours, and cases where the percentage increase in viscosity compared to the initial viscosity was <20% were considered “OK”, and cases where the percentage increase was ≥20% or where measurement was not possible were considered “NG”. Viscosity measurements were performed by the same method as described in the viscosity section above.

TABLE 1

| | Practical | Practical | Practical | Practical | Practical | Practical |
|---|---|---|---|---|---|---|
| Component | Example 1 | Example 2 | Example 3 | Example 4 | Example 5 | Example 6 |
| a-1 M(Vi)₂₅-T(Ph)₇₅ | 64 | 64 | 64 | 64 | 63.2 | 63.4 |
| a-2 M(Vi)₁₃-D(Ep)₂₄-T(Ph)₄₆—(OMe)₁₇ | 1 | 1 | 1 | 1 | 1 | 1 |
| a-3 D(Vi)₄ | 3.9 | 3.9 | 3.9 | 3.9 | — | — |
| a-4 M(Vi)₄Q | — | — | — | — | 6.4 | 6.4 |
| b-1 M(H)₆₀—T(Ph)₄₀ | 3.1 | 3.1 | 3.1 | 3.1 | 1.5 | — |
| b-2 M(H)—D(Ph₂)—M(H) | 28 | 28 | 28 | 28 | 27.9 | 28.2 |
| b-3 M(H)₆₂Q₃₈ | — | — | — | — | — | 1.0 |
| Total of Component a and Component b | 100 | 100 | 100 | 100 | 100 | 100 |
| c-1 | 0.05 | 0.1 | 0.5 | 1 | 0.5 | 0.5 |
| D | 12 ppm | 12 ppm | 12 ppm | 12 ppm | 4 ppm | 4 ppm |
| e-1 | 1.4 | 1.4 | 1.4 | 1.4 | — | — |
| e-2 | — | — | — | — | 0.1 | 0.1 |
| H/Vi | 1.13 | 1.13 | 1.13 | 1.13 | 1.0 | 1.0 |
| Evaluation | | | | | | |
| Viscosity (mPa · s) | 550 | 540 | 510 | 500 | 530 | 500 |
| Hardness | D65 | D65 | D65 | D65 | D60 | D61 |
| Light Transmittance (150° C. 8 h) | OK | OK | OK | OK | OK | OK |
| Wettability Ratio | 1.5 | 1.4 | 1.4 | 1.4 | 1.4 | 1.2 |
| Curability | OK | OK | OK | OK | OK | OK |
| Pot Life | OK | OK | OK | OK | OK | OK |

TABLE 2

| | Practical | Practical | Practical | Practical | Practical | Practical | Practical | Practical |
|---|---|---|---|---|---|---|---|---|
| Component | Example 7 | Example 8 | Example 9 | Example 10 | Example 11 | Example 12 | Example 13 | Example 14 |
| a-1 M(Vi)₂₅-T(Ph)₇₅ | 63.2 | 63.2 | 63.2 | 63.2 | 63.4 | 62.3 | 64 | — |
| a-2 M(Vi)₁₃-D(Ep)₂₄-T(Ph)₄₆—(OMe)₁₇ | 1 | 1 | 1 | 1 | 1 | 1 | 1 | 1 |
| a-3 D(Vi)₄ | — | — | — | — | — | 1.9 | 4 | 5 |
| a-4 M(Vi)₄Q | 6.4 | 6.4 | 6.4 | 6.4 | 6.4 | 2.9 | — | 6.0 |
| a-5 M₅-M(Vi)₁₇-T₃₉-T(Ph)₃₉ | — | — | — | — | — | — | — | 64.7 |
| b-1 M(H)₆₀—T(Ph)₄₀ | 1.5 | 1.5 | 1.5 | 1.5 | — | 6 | 3 | 2.5 |
| b-2 M(H)—D(Ph₂)—M(H) | 27.9 | 27.9 | 27.9 | 27.9 | 28.2 | 25.9 | 28 | 25.8 |
| b-3 M(H)₆₂Q₃₈ | — | — | — | — | 1.0 | — | — | — |
| Total of Component a and Component b | 100 | 100 | 100 | 100 | 100 | 100 | 100 | 100 |
| c-1 | — | — | — | 0.5 | 0.5 | 0.1 | 0.1 | 0.1 |
| c-2 | 0.5 | — | — | — | — | — | — | — |
| c-3 | — | 0.5 | — | — | — | — | — | — |
| c-4 | — | — | 0.5 | 0.5 | 0.5 | — | — | — |
| D | 4 ppm | 4 ppm | 4 ppm | 4 ppm | 4 ppm | 7 ppm | 11 ppm | 4 ppm |
| e-1 | — | — | — | — | — | — | 0.7 | — |
| e-2 | 0.1 | 0.1 | 0.1 | 0.1 | 0.1 | 0.2 | — | 0.1 |
| H/Vi | 1.0 | 1.0 | 1.0 | 1.0 | 1.0 | 1.0 | 1.0 | 1.0 |
| Evaluation | | | | | | | | |
| Viscosity (mPa · s) | 550 | 500 | 510 | 480 | 520 | 540 | 540 | 600 |
| Hardness | D60 | D60 | D60 | D60 | D63 | D60 | D60 | D61 |
| Light Transmittance (150° C. 8 h) | OK | OK | OK | OK | OK | OK | OK | OK |
| Wettability Ratio | 1.4 | 1.5 | 1.5 | 1.2 | 1.1 | 1.4 | 1.4 | 1.5 |
| Curability | OK | OK | OK | OK | OK | OK | OK | OK |
| Pot Life | OK | OK | OK | OK | OK | OK | OK | OK |

TABLE 3

| | Comparative | Comparative | Comparative | Comparative | Comparative | Comparative | Comparative |
|---|---|---|---|---|---|---|---|
| Component | Example 1 | Example 2 | Example 3 | Example 4 | Example 5 | Example 6 | Example 7 |
| a-1 M(Vi)₂₅-T(Ph)₇₅ | 64 | 64 | 64 | 64 | 64 | 64 | 64 |
| a-2 M(Vi)₁₃-D(Ep)₂₄-T(Ph)₄₆—(OMe)₁₇ | 1 | 1 | 1 | 1 | 1 | 1 | 1 |
| a-3 D(Vi)₄ | 3.9 | 3.9 | 3.9 | 3.9 | 3.9 | 3.9 | 3.9 |
| b-1 M(H)₆₀—T(Ph)₄₀ | 3.1 | 3.1 | 3.1 | 3.1 | 3.1 | 3.1 | 3.1 |
| b-2 M(H)—D(Ph₂)—M(H) | 28 | 28 | 28 | 28 | 28 | 28 | 28 |
| Total of Component a and Component b | 100 | 100 | 100 | 100 | 100 | 100 | 100 |
| c′-1 | — | 0.1 | — | — | — | — | — |
| c′-2 | — | — | 0.1 | — | — | — | — |
| c′-3 | — | — | — | 0.1 | — | — | — |
| c′-4 | — | — | — | — | 0.1 | — | — |
| c′-5 | — | — | — | — | — | 0.1 | — |
| c′-6 | — | — | — | — | — | — | 0.1 |
| d | 12 ppm | 12 ppm | 12 ppm | 12 ppm | 12 ppm | 12 ppm | 12 ppm |
| e-1 | 1.4 | 1.4 | 1.4 | 1,4 | 1.4 | 1.4 | 1.4 |
| H/Vi | 1.13 | 1.13 | 1.13 | 1.13 | 1.13 | 1.13 | 1.13 |
| Evaluation | | | | | | | |
| Viscosity (mPa · s) | 554 | 540 | 510 | 540 | 540 | 540 | 540 |
| Hardness | D65 | D65 | D65 | D65 | D65 | D65 | D65 |
| Light Transmittance (150° C. 8 h) | OK | OK | OK | OK | OK | OK | OK |
| Wettability Ratio | 3.0 | 3.1 | 3.0 | 2.2 | 3.6 | 3.3 | 3.2 |
| Curability | OK | OK | OK | OK | OK | OK | OK |
| Pot Life | OK | OK | OK | OK | OK | OK | OK |

TABLE 4

| | Comparative | Comparative | Comparative | Comparative | Comparative | Comparative |
|---|---|---|---|---|---|---|
| Component | Example 8 | Example 9 | Example 10 | Example 11 | Example 12 | Example 13 |
| a-1 M(Vi)₂₅-T(Ph)₇₅ | 64 | 64 | 64 | 64 | 64 | 64 |
| a-2 M(Vi)₁₃-D(Ep)₂₄—T(Ph)₄₆—(OMe)₁₇ | 1 | 1 | 1 | 1 | 1 | 1 |
| a-3 D(Vi)₄ | 3.9 | 3.9 | 3.9 | 3.9 | 3.9 | 3.9 |
| b-1 M(H)₆₀—T(Ph)₄₀ | 3.1 | 3.1 | 3.1 | 3.1 | 3.1 | 3.1 |
| b-2 M(H)—D(Ph₂)—M(H) | 28 | 28 | 28 | 28 | 28 | 28 |
| Total of Component a and Component b | 100 | 100 | 100 | 100 | 100 | 100 |
| c′-7 | 0.1 | — | — | — | — | — |
| c′-8 | — | 0.1 | — | — | — | — |
| c′-9 | — | — | 0.1 | — | — | — |
| c′-10 | — | — | — | 0.1 | — | — |
| c′-11 | — | — | — | — | 0.1 | — |
| c′-12 | — | — | — | — | — | 0.1 |
| d | 12 ppm | 12 ppm | 12 ppm | 12 ppm | 12 ppm | 12 ppm |
| e-1 | 1.4 | 1.4 | 1.4 | 1.4 | 1.4 | 1.4 |
| H/Vi | 1.13 | 1.13 | 1.13 | 1.13 | 1.13 | 1.13 |
| Evaluation | | | | | | |
| Viscosity (mPa · s) | 540 | 540 | 540 | 540 | 540 | 540 |
| Hardness | D65 | D65 | D65 | D65 | D65 | D65 |
| Light Transmittance (150° C. 8 h) | OK | OK | OK | OK | OK | OK |
| Wettability Ratio | 3.3 | 3.2 | 3.2 | 3.5 | 3.2 | 3.1 |
| Curability | OK | OK | OK | OK | OK | OK |
| Pot Life | OK | OK | OK | OK | OK | OK |

TABLE 5

| | Comparative | Comparative | Comparative | Comparative | Comparative | Comparative |
|---|---|---|---|---|---|---|
| Component | Example 14 | Example 15 | Example 16 | Example 17 | Example 18 | Example 19 |
| a-1 M(Vi)₂₅-T(Ph)₇₅ | 64 | 64 | 64 | 64 | 63.5 | 63.3 |
| a-2 M(Vi)₁₃-D(Ep)₂₄-T(Ph)₄₆—(OMe)₁₇ | 1 | 1 | 3 | 1 | 2.6 | 2.7 |
| a-3 D(Vi)₄ | 3.9 | 3.9 | 3.9 | 3.9 | 4.3 | 4 |
| b-1 M(H)₆₀—T(Ph)₄₀ | 3.1 | 3.1 | 3.1 | 3.1 | — | — |
| b-2 M(H)—D(Ph₂)—M(H) | 28 | 28 | 28 | 28 | 29.6 | 30 |
| Total of Component a and Component b | 100 | 100 | 100 | 100 | 100 | 100 |
| c′-13 | 0.1 | — | — | — | — | — |
| c′-14 | — | 0.1 | — | — | — | — |
| c′-15 | — | — | 0.1 | — | — | — |
| c′-16 | — | — | — | 0.1 | — | — |
| d | 12 ppm | 12 ppm | 12 ppm | 12 ppm | 8 ppm | 12 ppm |
| e-1 | 1.4 | 1.4 | 1.4 | 1.4 | — | 0.7 |
| e-2 | — | — | — | — | 0.45 | — |
| H/Vi | 1.13 | 1.13 | 1.13 | 1.13 | 1.0 | 1.0 |
| Evaluation | | | | | | |
| Viscosity (mPa · s) | 540 | Did not mix | Did not mix | Did not mix | 457 | 519 |
| Hardness | D65 | | | | D63 | D62 |
| Light Transmittance (150° C. 8 h) | OK | | | | NG | NG |
| Wettability Ratio | 3.1 | | | | 4.0 | 4.0 |
| Curability | OK | | | | NG | OK |
| Pot Life | OK | | | | OK | OK |

TABLE 6

| | Comparative | Comparative | Comparative | Comparative | Comparative | Comparative |
|---|---|---|---|---|---|---|
| Component | Example 20 | Example 21 | Example 22 | Example 23 | Example 24 | Example 25 |
| a-1 M(Vi)₂₅-T(Ph)₇₅ | 58.5 | 63.5 | 63.5 | — | — | — |
| a-2 M(Vi)₁₃-D(Ep)₂₄—T(Ph)₄₆—(OMe)₁₇ | 2.6 | 2.6 | 1 | 2.5 | 2.6 | 1 |
| a-3 D(Vi)₄ | — | 3.9 | 3.1 | 5.1 | 5.1 | — |
| a-4 M(Vi)₄Q | 7.3 | — | — | — | — | 5.8 |
| a-5 M₅-M(Vi)₁₇-T₃₉-T(Ph)₃₉ | — | — | — | 63.4 | 63.4 | 64.9 |
| b-1 M(H)₆₀—T(Ph)₄₀ | 4.6 | — | 2.4 | — | — | — |
| b-2 M(H)—D(Ph₂)—M(H) | 27 | 30 | 30 | 29 | 29 | 28.3 |
| Total of Component a and Component b | 100 | 100 | 100 | 100 | 100 | 100 |
| D | 10 ppm | 17.5 ppm | 12 ppm | 15 ppm | 12 ppm | 8 ppm |
| e-1 | 0.7 | 0.7 | 0.7 | 0.7 | 0.7 | 0.7 |
| H/Vi | 1.13 | 1.0 | 1.24 | 1.0 | 1.0 | 1.0 |
| Evaluation | | | | | | |
| Viscosity (mPa · s) | 500 | 535 | 500 | 490 | 500 | 540 |
| Hardness | D55 | D65 | D43 | D63 | D62 | D51 |
| Light Transmittance (150° C. 8 h) | OK | NG | OK | NG | NG | NG |
| Wettability Ratio | 3.5 | 4.0 | 3.0 | 1.5 | 1.4 | 1.5 |
| Curability | OK | OK | OK | NG | NG | OK |
| Pot Life | NG | OK | NG | NG | NG | NG |

From the test results for the practical examples and comparative examples described above, curable silicone compositions of the present invention exhibited an effective pot life in practical terms and superior curability at low temperatures. In addition, because the curable silicone compositions of the present invention exhibited superior wettability on base materials, a cured product having a smooth surface shape could be formed. Moreover, curable silicone compositions of the present invention could form a cured product that exhibited high hardness and excellent transparency even after heating.

### Practical Examples 15 to 22 and Comparative Examples 1 and 18 to 36

The different components were mixed to give the compositions shown in the tables below (parts by mass) to prepare curable silicone compositions. Note that the quantity of curing catalyst of component d is presented as the quantity of platinum atoms (ppm) included in component d. Note also that the compositions of Comparative Examples 1 and 18 to 25 are the same as the aforementioned compositions of Comparative Examples 1 and 18 to 25.

Viscosity, cured product hardness, curability, and pot life were evaluated in the same manner as the evaluations of Practical Examples 1 to 14 and Comparative Examples 1 to 25 in Tables 1 to 6 above. Except for heat treatment at 150° C. for 48 hours, light transmittance of the cured products was evaluated in the same manner as the light transmittance of the cured products of Practical Examples 1 to 14 and Comparative Examples 1 to 25 in Tables 1 to 6 above. More specifically, evaluations were carried out as follows.

[Viscosity]

The viscosity of the curable silicone compositions was measured at 25° C. and 20 s⁻¹ using a viscoelasticity measurement apparatus (MCR-302, manufactured by Anton Paar Co.) in accordance with the method described in JIS K 7117-1:1999.

[Hardness of the Cured Product]

The curable silicone compositions obtained were heated at 90° C. for 20 minutes to prepare 10-mm-thick cured products. The hardness of the cured products was measured with a type D durometer as specified in JIS K 7215-1986 “Testing Methods for Durometer Hardness of Plastics”.

[Light Transmittance of the Cured Product]

The curable silicone compositions obtained (2 mm thickness) were heat treated at 150° C. for 48 hours to produce test pieces. The light transmittance of these test pieces was measured at 25° C. using a self-recording spectrophotometer capable of measuring at any wavelength in the visible light range (wavelength 400 nm to 700 nm). Transmittance of 450 nm light of ≥95% was considered “OK”.

[Curability]

The curable silicone compositions obtained were measured using a curability tester (moving die rheometer (MDR)) at a temperature of 90° C., and when the time from immediately after measurement until saturation torque was reached was <5 minutes, the result was considered “OK”, and when the time was ≥5 minutes, the result was considered “NG”.

[Pot Life]

The viscosity was measured after the curable silicone compositions obtained had been held at a temperature at 40° C. for 4 hours, and cases where the percentage increase in viscosity compared to the initial viscosity was <20% were considered “OK”, and cases where the percentage increase was ≥20% or where measurement was not possible were considered “NG”. Viscosity measurements were performed by the same method as described in the viscosity section above.

TABLE 7

| | Comparative | Practical | Comparative | Comparative | Comparative | Comparative |
|---|---|---|---|---|---|---|
| Component | Example 1 | Example 15 | Example 26 | Example 27 | Example 28 | Example 29 |
| a-1 M(Vi)₂₅-T(Ph)₇₅ | 64 | 61.6 | 61.55 | 61.6 | 61.6 | 62.83 |
| a-2 M(Vi)₁₃-D(Ep)₂₄-T(Ph)₄₆—(OMe)₁₇ | 1 | 1 | 1 | 1 | 1 | 1 |
| a-3 D(Vi)₄ | 3.9 | — | — | — | — | — |
| a-4 M(Vi)₄Q | — | 6.33 | 6.33 | 6.33 | 6.33 | 6.33 |
| b-1 M(H)₆₀—T(Ph)₄₀ | 3.1 | 1.5 | 1.5 | 1.5 | 1.5 | 1.5 |
| b-2 M(H)—D(Ph₂)—M(H) | 28 | 29.57 | 29.62 | 29.57 | 29.57 | 28.34 |
| Total of Component a and Component b | 100 | 100 | 100 | 100 | 100 | 100 |
| D | 12 ppm | 4 ppm | 4 ppm | 4 ppm | 4 ppm | 4 ppm |
| e-1 | 1.4 | — | 0.2 | — | — | — |
| e-2 | — | 0.1 | — | — | — | 0.1 |
| e-3 | — | — | — | 0.1 | — | — |
| e-4 | — | — | — | — | 0.1 | — |
| H/Vi | 1.13 | 1.0 | 1.0 | 1.0 | 1.0 | 0.95 |
| Evaluation | | | | | | |
| Viscosity (mPa · s) | 554 | 530 | 530 | 530 | 530 | 600 |
| Hardness | D65 | D62 | D62 | D62 | D62 | D62 |
| Light Transmittance (150° C. 48 h) | NG | OK | OK | OK | OK | OK |
| Curability | OK | OK | OK | NG | NG | NG |
| Pot Life | OK | OK | NG | NG | NG | OK |

TABLE 8

| | Comparative | Comparative | Comparative | Comparative | Comparative | Comparative |
|---|---|---|---|---|---|---|
| Component | Example 30 | Example 31 | Example 32 | Example 33 | Example 34 | Example 35 |
| a-1 M(Vi)₂₅-T(Ph)₇₅ | 63.16 | 63.16 | 62.4 | 62.77 | 62.43 | 62.4 |
| a-2 M(Vi)₁₃-D(Ep)₂₄-T(Ph)₄₆—(OMe)₁₇ | 2.5 | 2.5 | 2.5 | 2.5 | 1 | 1 |
| a-3 D(Vi)₄ | — | — | 2.82 | 1.41 | 3.82 | 3.82 |
| a-4 M(Vi)₄Q | 3.82 | 3.82 | 1 | 2.41 | — | — |
| b-1 M(H)₆₀—T(Ph)₄₀ | — | — | — | — | 3.0 | 3.0 |
| b-2 M(H)—D(Ph₂)—M(H) | 30.52 | 30.52 | 31.28 | 30.91 | 29.75 | 29.78 |
| Total of Component a and Component b | 100 | 100 | 100 | 100 | 100 | 100 |
| D | 8 ppm | 3 ppm | 8 ppm | 8 ppm | 8 ppm | 6 ppm |
| e-2 | 0.4 | 0.4 | 0.45 | 0.5 | 0.85 | 0.3 |
| H/Vi | 1.0 | 1.0 | 1.0 | 1.0 | 1.0 | 1.0 |
| Evaluation | | | | | | |
| Viscosity (mPa · s) | — | — | — | — | — | — |
| Hardness | D53 | D53 | D60 | D58 | — | — |
| Light Transmittance (150° C. 48 h) | NG | OK | NG | NG | NG | OK |
| Curability | OK | NG | NG | NG | OK | NG |
| Pot Life | OK | — | — | — | OK | OK |

TABLE 9

| | Practical | Practical | Practical | Practical | Practical | Practical | Practical |
|---|---|---|---|---|---|---|---|
| Component | Example 16 | Example 17 | Example 18 | Example 19 | Example 20 | Example 21 | Example 22 |
| a-1 M(Vi)₂₅-T(Ph)₇₅ | 61.57 | 61.54 | 61.8 | 62.26 | 62.68 | 62.48 | 60.64 |
| a-2 M(Vi)₁₃-D(Ep)₂₄-T(Ph)₄₆—(OMe)₁₇ | 1 | 1 | 1 | 1 | 1 | 1 | 1 |
| a-3 D(Vi)₄ | — | — | — | — | — | 1.33 | 1.33 |
| a-4 M(Vi)₄Q | 6.34 | 6.34 | 6.33 | 6.34 | 6.34 | 2.5 | 3.4 |
| b-1 M(H)₆₀—T(Ph)₄₀ | 1.5 | 1.5 | — | 2.5 | — | 3 | 6 |
| b-2 M(H)—D(Ph₂)—M(H) | 29.59 | 29.62 | 29.67 | 27.9 | 27.98 | 29.69 | 27.63 |
| b-3 M(H)₆₂Q₃₈ | — | — | 1.2 | — | 2 | — | — |
| Total of Component a and Component b | 100 | 100 | 100 | 100 | 100 | 100 | 100 |
| D | 3 ppm | 4 ppm | 4 ppm | 4 ppm | 4 ppm | 6 ppm | 6 ppm |
| e-2 | 0.2 | 0.3 | 0.1 | 0.1 | 0.1 | 0.35 | 0.35 |
| H/Vi | 1.0 | 1.0 | 1.0 | 1.0 | 1.0 | 1.16 | 1.1 |
| Evaluation | | | | | | | |
| Viscosity (mPa · s) | 502 | 505 | 530 | 600 | 600 | 600 | 500 |
| Hardness | D62 | D62 | D65 | D55 | D55 | D55 | D62 |
| Light Transmittance (150° C. 48 h) | OK | OK | OK | OK | OK | OK | OK |
| Curability | OK | OK | OK | OK | OK | OK | OK |
| Pot Life | OK | OK | OK | OK | OK | OK | OK |

TABLE 10

| | | Comparative | Comparative | Comparative |
|---|---|---|---|---|
| Component | | Example 36 | Example 18 | Example 19 |
| a-1 | M(Vi)₂₅-T(Ph)₇₅ | — | 63.5 | 63.3 |
| a-2 | M(Vi)₁₃-D(Ep)₂₄- | 1 | 2.6 | 2.7 |
| | T(Ph)₄₆-(OMe)₁₇ | | | |
| a-3 | D(Vi)₄ | — | 4.3 | 4 |
| a-4 | M(Vi)₄Q | 6.33 | — | — |
| a-6 | D(Vi)₂₅-D(Ph₂)₃₀-T(Ph)₄₅ | 62.35 | — | — |
| b-1 | M(H)₆₀-T(Ph)₄₀ | 1.5 | — | — |
| b-2 | M(H)-D(Ph₂)-M(H) | 28.82 | 29.6 | 30 |

| | | | |
|---|---|---|---|
| Total of Component a | 100 | 100 | 100 |
| and Component b | | | |
| d | 4 ppm | 8 ppm | 12 ppm |
| e-1 | — | — | 0.7 |
| e-2 | 0.1 | 0.45 | — |
| H/Vi | 1.07 | 1.0 | 1.0 |
| Evaluation | | | |
| Viscosity (mPa · s) | — | 457 | 519 |
| Hardness | — | D63 | D62 |
| Light Transmittance (150° C. 48 h) | NG | NG | NG |
| Curability | — | NG | OK |
| Pot Life | — | OK | OK |

TABLE 11

| | Comparative | Comparative | Comparative | Comparative | Comparative | Comparative |
|---|---|---|---|---|---|---|
| Component | Example 20 | Example 21 | Example 22 | Example 23 | Example 24 | Example 25 |
| a-1 M(Vi)₂₅-T(Ph)₇₅ | 58.5 | 63.5 | 63.5 | — | — | — |
| a-2 M(Vi)₁₃-D(Ep)₂₄-T(Ph)₄₆—(OMe)₁₇ | 2.6 | 2.6 | 1 | 2.5 | 2.6 | 1 |
| a-3 D(Vi)₄ | — | 3.9 | 3.1 | 5.1 | 5.1 | — |
| a-4 M(Vi)₄Q | 7.3 | — | — | — | — | 5.8 |
| a-5 M₅-M(Vi)₁₇-T₃₉-T(Ph)₃₉ | — | — | — | 63.4 | 63.4 | 64.9 |
| b-1 M(H)₆₀—T(Ph)₄₀ | 4.6 | — | 2.4 | — | — | — |
| b-2 M(H)—D(Ph₂)—M(H) | 27 | 30 | 30 | 29 | 29 | 28.3 |
| Total of Component a and Component b | 100 | 100 | 100 | 100 | 100 | 100 |
| D | 10 ppm | 17.5 ppm | 12 ppm | 15 ppm | 12 ppm | 8 ppm |
| e-1 | 0.7 | 0.7 | 0.7 | 0.7 | 0.7 | 0.7 |
| H/Vi | 1.13 | 1.0 | 1.24 | 1.0 | 1.0 | 1.0 |
| Evaluation | | | | | | |
| Viscosity (mPa · s) | 500 | 535 | 500 | 490 | 500 | 540 |
| Hardness | D55 | D65 | D43 | D63 | D62 | D51 |
| Light Transmittance (150° C. 48 h) | NG | NG | NG | NG | NG | NG |
| Curability | OK | OK | OK | NG | NG | OK |
| Pot Life | NG | OK | NG | NG | NG | NG |

From the test results for the practical examples and comparative examples described above, curable silicone compositions of the present invention exhibited an effective pot life in practical terms and superior curability at low temperatures. In addition, curable silicone compositions of the present invention could form a cured product that had excellent hardness and exhibited excellent transparency even after heating for a long period of time.

### INDUSTRIAL APPLICABILITY

The curable silicone composition of the present invention exhibits an effective pot life in practical terms and excellent curability at low temperature and can form a cured product that has excellent surface smoothness, is transparent, and has high hardness. Because of this, the curable silicone composition of the present invention is extremely useful for encapsulant applications when manufacturing optical semiconductor devices, for example.

1. A curable silicone composition, comprising:
(A) a resinous alkenyl group-containing organopolysiloxane which has at least two alkenyl groups and at least one aryl group per molecule-;
(B) a resinous organo-hydrogen polysiloxane which has at least two silicon atom-bonded hydrogen atoms per molecule;
(C) an additive having a wettability improving effect selected from a molecular-chain side chain polyether-modified organopolysiloxane, a phenol-modified organopolysiloxane, a terminal hydroxy group-containing dimethylpolysiloxane that does not include an aryl group, and a phenolic antioxidant, and also combinations thereof-,and,
(D) a curing catalyst.

2. The curable silicone composition as claimed in claim 1, further comprising a straight-chain organo-hydrogen polysiloxane.

3. The curable silicone composition as claimed in claim 1, wherein the polyether group of the molecular-chain side chain polyether-modified organopolysiloxane of component (C) includes a polyoxyethylene unit.

4. The curable silicone composition as claimed in claim 1, wherein the phenol-modified organopolysiloxane of component (C) is a straight chain and includes a phenol group-containing organic group at both ends of the molecular chain.

5. The curable silicone composition as claimed in claim 1, wherein the terminal hydroxy group-containing dimethylpolysiloxane that does not include an aryl group of component (C) is a straight chain and includes a hydroxy group at both ends of the molecular chain.

6. The curable silicone composition as claimed in claim 1, wherein the phenolic antioxidant of component (C) is 2,6-di-tert-butyl-p-cresol.

7. The curable silicone composition as claimed in claim 1, wherein the content of (C) additive having a wettability improving effect is ≥0.01 mass % and ≤10 mass % of the total mass of alkenyl group-containing organopolysiloxane and organo-hydrogen polysiloxane.

8. The curable silicone composition as claimed in claim 1, wherein the content of resinous organo-hydrogen polysiloxane (B) is ≥1 mass % of the total mass of alkenyl group-containing organopolysiloxane and organo-hydrogen polysiloxane.

9. The curable silicone composition as claimed in claim 1, wherein the curing catalyst (D) is a platinum-based catalyst and includes ≥0.01 ppm and ≤15 ppm of platinum atoms relative to the total mass of curable silicone composition.

10. The curable silicone composition as claimed in claim 1, wherein a molar ratio (H/Vi) of hydrogen atoms to alkenyl groups originating from the organopolysiloxane component is 0.9 to 1.3.

11. The curable silicone composition as claimed in claim 1, further comprising, other than component (A), alkenyl group-containing organopolysiloxane comprising solely epoxy group-containing resinous organopolysiloxane, alkenyl group-containing cyclic organopolysiloxane and/or M units and Q units.

12. A curable silicone composition, comprising:
(A) a resinous alkenyl group-containing organopolysiloxane which has at least two alkenyl groups and at least one aryl group per molecule;
(F) an alkenyl group-containing organopolysiloxane comprising solely M units and Q units;
(B) a resinous organo-hydrogen polysiloxane which has at least two silicon atom-bonded hydrogen atoms per molecule;
(E) ethynylcyclohexanol; and,
(D) a curing catalyst;
wherein a molar ratio (H/Vi) of hydrogen atoms to alkenyl groups originating from the organopolysiloxane component is 0.98 to 1.2; and,
the content of resinous organopolysiloxane that contains alkenyl groups that are bonded to silicon atoms of siloxane units (D units), which are represented by SiO_{2/2}, is ≤50 mass % of the total mass of alkenyl group-containing organopolysiloxane and organo-hydrogen polysiloxane.

13. The curable silicone composition as claimed in claim 12, wherein the content of (F) alkenyl group-containing organopolysiloxane comprising solely M units and Q units is ≥2 mass % and ≤20 mass % of the total mass of alkenyl group-containing polysiloxane and organo-hydrogen polysiloxane.

14. The curable silicone composition as claimed in claim 12, wherein the content of (B) resinous organo-hydrogen polysiloxane is ≥1 mass % and ≤15 mass % of the total mass of alkenyl group-containing organopolysiloxane and organo-hydrogen polysiloxane.

15. The curable silicone composition as claimed in claim 12, wherein the curing catalyst (D) is a platinum-based catalyst and contains ≥0.01 ppm and ≤8 ppm of platinum atoms relative to the total mass of curable silicone composition.

16. The curable silicone composition as claimed in claim 12, wherein the straight-chain organo-hydrogen polysiloxane is contained in an amount of ≥25 mass % relative to the total mass of resinous alkenyl group-containing organopolysiloxane of component (A).

17. An encapsulant comprising the curable silicone composition as claimed in claim 1.

18. An optical semiconductor device comprising a cured product of the encapsulant as claimed in claim 17.
